(19) United States
(12) Patent Application Publication
(10) Pub. No.: US 2026/0282544 A1
(43) Pub. Date: Sep. 17, 2026

(54) Array Substrate, Display Panel, and Display Apparatus

(71) Applicants: Peipei Wang, Beijing (CN); Honggui Jin, Beijing (CN); Yong Zhang, Beijing (CN); Pingyuan Sun, Beijing (CN); Ruomei Bian, Beijing (CN); Zhilong Duan, Beijing (CN); Yang Liu, Beijing (CN); Jiulei Zhou, Beijing (CN); Donghua Zhang, Beijing (CN); Yue Yang, Beijing (CN)

(72) Inventors: Peipei Wang, Beijing (CN); Honggui Jin, Beijing (CN); Yong Zhang, Beijing (CN); Pingyuan Sun, Beijing (CN); Ruomei Bian, Beijing (CN); Zhilong Duan, Beijing (CN); Yang Liu, Beijing (CN); Jiulei Zhou, Beijing (CN); Donghua Zhang, Beijing (CN); Yue Yang, Beijing (CN)

(21) Appl. No.: 18/996,646

(22) PCT Filed: Apr. 16, 2024
(86) PCT No.: PCT/CN2024/088127

§ 371 Date: Jan. 17, 2025

(30) Foreign Application Priority Data
May 26, 2023 (CN) 202310611587.9

(51) Int. Cl. H10D 86/40; G02F 1/1362; G02F 1/1368; H10D 86/60

(52) U.S. Cl. CPC H10D 86/441; G02F 1/136209; G02F 1/136286; G02F 1/1368; H10D 86/60

(57) ABSTRACT

An array substrate is provided, and includes a base, and a plurality of thin film transistors disposed on the base and distributed in an array. A thin film transistor of the plurality of thin film transistors includes: a gate pattern, disposed on the base; a semiconductor pattern, disposed on a side of the gate pattern away from the base, where an orthographic projection of the semiconductor pattern on the base is located within a range of an orthographic projection of the gate pattern on the base, and a boundary of the orthographic projection of the semiconductor pattern on the base has an interval with a boundary of the orthographic projection of the gate pattern on the base; a source pattern and a drain pattern. Along a first direction, the source pattern and the drain pattern are disposed at intervals, and electrically connected to two ends of the semiconductor pattern, respectively.

### CROSS-REFERENCE TO RELATED APPLICATIONS

This application is the United States national phase of International Patent Application No. PCT/CN 2024/088127 filed Apr. 16, 2024, and claims priority to Chinese Patent Application No. 202310611587.9, filed May 26, 2023, the disclosures of which are hereby incorporated by reference in their entireties.

### BACKGROUND OF THE INVENTION

### Field of the Invention The present disclosure relates to the field of display technologies, and in particular, to an array substrate, a display panel and a display apparatus.

### Description of Related Art

A liquid crystal display (Liquid Crystal Display; abbreviation: LCD) projector is a projector device that displays images by an LCD display panel, and has advantages of such as low cost and high portability, so it is highly favored by users. The display panel of the LCD projector works in a working environment with high brightness (e.g., the light intensity is more than 200,000 nits) for a long period of time, and in order to reduce the impact of light on characteristics of a thin film transistor, especially to reduce the impact of light on a semiconductor layer (also called an active layer or A-Si layer or channel layer, etc.) of the thin film transistor, the semiconductor layer needs to be light-shielded. Meanwhile, in order to improve the display effect of the projector, higher requirements for the light transmittance and pixel density (Pixels Per Inch; abbreviation: PPI) of the display panel have been put forward. How to improve the PPI of the display panel and improve the pixel aperture ratio of the display panel on the premise of ensuring the effective light-shielding of the semiconductor layer, is a problem that the current LCD projector device needs to solve urgently.

### SUMMARY OF THE INVENTION

On the one hand, an array substrate is provided. The array substrate includes a base, and a plurality of thin film transistors disposed on the base and distributed in an array. A thin film transistor of the plurality of thin film transistors includes a gate pattern, a semiconductor pattern, a source pattern, and a drain pattern. The gate pattern is disposed on the base, and the gate pattern includes a first sidewall and a second sidewall disposed opposite to each other along a first direction, the first sidewall is near the source pattern, and the second sidewall is near the drain pattern. The semiconductor pattern is disposed on a side of the gate pattern away from the base, where an orthographic projection of the semiconductor pattern on the base is located within a range of an orthographic projection of the gate pattern on the base, and a boundary of the semiconductor pattern has an interval with a boundary of the gate pattern. The source pattern and the drain pattern are disposed on a side of the semiconductor pattern away from the base, and the source pattern and the drain pattern are disposed at intervals along the first direction, and electrically connected to two ends of the semiconductor pattern along the first direction, respectively. Along the first direction, an interval between an end of the source pattern near the first sidewall and the semiconductor pattern is less than an interval between an end of the drain pattern near the second sidewall and the semiconductor pattern. An interval between the semiconductor pattern and the first sidewall is less than an interval between the semiconductor pattern and the second sidewall.

In some embodiments, the gate pattern further includes a third sidewall and a fourth sidewall disposed opposite to each other along a second direction, the second direction intersects with the first direction. An interval between the semiconductor pattern and the third sidewall, an interval between the semiconductor pattern and the fourth sidewall, and the interval between the semiconductor pattern and the second sidewall are roughly equal.

In some embodiments, the interval between the semiconductor pattern and the first sidewall is D1, the interval between the semiconductor pattern and the second sidewall is D2, and a ratio of D1 to D2 is 0.5 to 0.6.

In some embodiments, the drain pattern includes a first sub-portion and a second sub-portion. The first sub-portion extends along a second direction and is electrically connected to the semiconductor pattern. An orthographic projection of the first sub-portion on the base is located within a range of the orthographic projection of the gate pattern on the base. The second sub-portion is connected with the first sub-portion; along the first direction, an end portion of the second sub-portion away from the first sub-portion is flush with the second sidewall, or extends out of the boundary of the gate pattern. The second direction intersects with the first direction.

In some embodiments, along the first direction, a size of an overlapped part of the source pattern with the semiconductor pattern and a size of an overlapped part of the drain pattern with the semiconductor pattern are roughly equal, and both are larger than an interval between the source pattern and the drain pattern. A size of the semiconductor pattern along a second direction is greater than an interval between the source pattern and the drain pattern.

In some embodiments, along the first direction, a size of an overlapped part of the source pattern with the semiconductor pattern and a size of an overlapped part of the drain pattern with the semiconductor pattern are D3, and D3 is 3 μm to 3.85 μm. A size of the semiconductor pattern along the second direction is D4, and D4 is 3 μm to 3.7 μm; and the interval between the source pattern and the drain pattern is D5, and D5 is 1.8 μm to 2.4 μm.

In some embodiments, the array substrate further includes a pixel electrode. The pixel electrode is located on a same film layer as the semiconductor pattern, where an orthographic projection of the pixel electrode on the base has an interval with the orthographic projection of the gate pattern on the base. The pixel electrode includes a lap joint portion, and the lap joint portion is electrically connected to the drain pattern. Also, a size of the lap joint portion along the first direction is greater than a size of the lap joint portion along a second direction. The size of the lap joint portion along the first direction is D6, and D6 is 6.1 μm to 6.5 μm; and/or the size of the lap joint portion along the second direction is D7, and D7 is 1.4 μm to 1.8 μm.

In some embodiments, the array substrate further includes a plurality of data lines and a plurality of common voltage signal lines. The plurality of data lines and the plurality of common voltage signal lines are arranged in alternating lines along the first direction, and the plurality of data lines and the plurality of common voltage signal lines are disposed on a same layer as the source pattern and the drain pattern. An interval between orthographic projections of the pixel electrode and a common voltage signal line of the plurality of common voltage signal lines on the base is less than an interval between orthographic projections of the pixel electrode and a data line of the plurality of data lines on the base.

In some embodiments, the array substrate further includes a plurality of gate lines arranged at intervals along the second direction. The plurality of gate lines are disposed on a same layer as the gate pattern, and each gate line of the plurality of gate lines extends along the first direction, and a gate line of the plurality of gate lines is electrically connected to the gate pattern. Along the second direction, an interval between the pixel electrode and the gate pattern, and an interval between the pixel electrode and the gate line are equal.

In some embodiments, the interval between the pixel electrode and the gate pattern is less than the interval between the pixel electrode and the common voltage signal line.

In some embodiments, along the first direction, a size of the data line is roughly equal to a size of the common voltage signal line, and the size of the data line along the first direction is smaller than a size of an overlapped part of the source pattern with the semiconductor pattern along the first direction.

In some embodiments, an interval between the pixel electrode and the common voltage signal line along the first direction is D8, and D8 is 2.4 μm to 2.8 μm. An interval between the pixel electrode and the data line along the first direction is D9, and D9 is 3.0 μm to 3.4 μm. An interval between the pixel electrode and a grid line comprised in the array substrate along the second direction is D10, and D10 is 2.0 μm to 2.4 μm. Sizes of the data line and the common voltage signal line along the first direction are D11, and D11 is 2.4 μm to 2.8 μm.

In some embodiments, the array substrate further includes a common electrode. The common electrode is located on a side of the source pattern and the drain pattern away from the base, and includes at least one electrode stripe extending along the second direction. Along the second direction, an orthographic projection of an end of an electrode stripe of the at least one electrode stripe away from the drain pattern on the base is located outside a range of the orthographic projection of the pixel electrode on the base.

In some embodiments, along the second direction, an orthographic projection of an end of the electrode stripe near the drain pattern on the base is located within the range of the orthographic projection of the pixel electrode on the base, and partially overlaps with an orthographic projection of the drain pattern on the base. The common electrode further includes a first connecting portion, the first connecting portion is connected with an end portion of the electrode stripe near the drain pattern. Also, an orthographic projection of the first connecting portion on the base partially overlaps with the orthographic projection of the pixel electrode on the base.

In some embodiments, the common electrode further includes a plurality of slits disposed at intervals along the first direction. An electrode stripe of the at least one electrode stripe is included between two adjacent slits of the plurality of slits. Along the first direction, a size of a slit of the plurality of slits is larger than a size of the electrode stripe.

In some embodiments, along the second direction, an interval between an end of the electrode stripe away from the drain pattern and the pixel electrode is D12, and D12 is 0.9 μm to 1.1 μm. The size of the slit along the first direction is D13, and D13 is 2.6 μm to 2.9 μm. The size of the electrode stripe along the first direction is D14, and D14 is 1.9 μm to 2.1 μm.

In some embodiments, the semiconductor pattern includes a third sub-portion and a fourth sub-portion arranged along the first direction, and the third sub-portion is near the first sidewall, compared to the fourth sub-portion. An orthographic projection of the common electrode on the base covers an orthographic projection of the third sub-portion on the base, and does not overlap with an orthographic projection of the fourth sub-portion on the base.

In some embodiments, along the first direction, a size of the third sub-portion is D15, and D15 is 0.4 μm to 0.6 μm.

In some embodiments, a boundary of the orthographic projection of the common electrode on the base roughly overlaps with an orthographic projection of a boundary of the fourth sub-portion away from the third sub-portion on the base, and roughly overlaps with an orthographic projection of a boundary of the fourth sub-portion near the pixel electrode on the base.

On the other hand, a display panel is further provided. The display panel includes a color film substrate and the array substrate described according to any one of the above embodiments. The color film substrate is disposed opposite to the array substrate, and the color film substrate includes a black matrix, and an orthographic projection of the black matrix on the array substrate covers the thin film transistor of the array substrate.

In some embodiments, the drain pattern of the thin film transistor includes a first sub-portion and a second sub-portion; and a boundary of an orthographic projection of the black matrix on the base of the array substrate has intervals with a boundary of an orthographic projection of the gate pattern of the thin film transistor on the base, with a boundary of an orthographic projection of the semiconductor pattern of the thin film transistor on the base, and with a boundary of an orthographic projection of the source pattern of the thin film transistor on the base, and roughly overlaps with a boundary of the second sub-portion away from the first sub-portion.

In some embodiments, along the second direction, an interval between the orthographic projection of the semiconductor pattern on the base and the orthographic projection of the black matrix on the base is D16, and D16 is 6.4 μm to 6.7 μm. And/or, the semiconductor pattern includes a fifth sub-portion, the fifth sub-portion is located between the source pattern and the drain pattern, and a minimum interval between an orthographic projection of the fifth sub-portion on the base and the orthographic projection of the black matrix on the base is D17, and D17 is 5.7 μm to 6.0 μm.

In some embodiments, the array substrate includes a plurality of base platforms arranged in an array, the plurality of base platforms are disposed on a same layer as the source pattern and the drain pattern. The display panel further includes a spacer, and the spacer is disposed between the array substrate and the color film substrate, and connected to the array substrate and the color film substrate respectively. An orthographic projection of the spacer on the base is located within a range of an orthographic projection of a base platform of the plurality of base platforms on the base.

The black matrix includes a first extending segment and a second extending segment. An orthographic projection of the first extending segment on the base covers an orthographic projection of the thin film transistor on the base. An orthographic projection of the second extending segment on the base covers orthographic projections of the base platform and the spacer on the base. Along the second direction, a size of the first extending segment is smaller than a size of the second extending segment.

In some embodiments, a radial size of an end surface at which the spacer is connected to the color film substrate is D18, and D18 is 8.3 μm to 8.7 μm; and/or a minimum interval between an orthographic projection of the end surface at which the spacer is connected to the color film substrate, on the black matrix, and a boundary of the black matrix is D19, and D19 is 6.8 μm to 7.2 μm.

In some embodiments, the array substrate includes a common electrode, and the common electrode includes at least one electrode stripe extending along a second direction. An orthographic projection of the black matrix on the array substrate overlaps at least partially with an end portion of an electrode stripe of the at least one electrode stripe along the second direction.

On the other hand, a display apparatus is provided. The display apparatus includes a driving circuit board and the display panel described according to any one of the above embodiments. The driving circuit board is configured to transmit a control signal to the display panel.

### BRIEF DESCRIPTION OF THE DRAWINGS

In order to describe technical solutions in the present disclosure more clearly, drawings to be used in some embodiments of the present disclosure will be introduced briefly, and obviously, the drawings in the following description are merely drawings of some embodiments of the present disclosure, and those ordinary skilled in the art may further obtain other drawings according to these drawings. In addition, the drawings in the following description may be regarded as schematic diagrams, and are not limitations on an actual size of a product, an actual procedure of a method and an actual timing of a signal, etc., involved in the embodiments of the present disclosure.

FIG. 1 is a structural view of a display apparatus according to some embodiments.

FIG. 2 is a structural view of a display panel according to some embodiments.

FIG. 3 is a cross-sectional structural view of an array substrate according to some embodiments.

FIG. 4 is a planar structural view of an array substrate according to some embodiments.

FIG. 5 is a partially enlarged view of an A1 region in FIG. 4.

FIG. 6 is a partially enlarged view of an A2 region in FIG. 2.

FIG. 7 is an equivalent circuit view of a pixel circuit according to some embodiments.

FIG. 8 is another planar structural view of an array substrate according to some embodiments.

FIG. 9 is a partially enlarged view of an A3 region in FIG. 8.

FIG. 10 is a partially enlarged view of an A5 region in FIG. 2.

FIG. 11 is a partially enlarged view of an A4 region in FIG. 8.

FIG. 12 is a partially enlarged view of an A6 region in FIG. 2.

FIG. 13 is a partially enlarged view of an A7 region in FIG. 8.

FIG. 14 is another partial enlarged view of an A2 region in FIG. 2.

FIG. 15 is a partial enlarged view of an A8 region in FIG. 2.

FIG. 16 is another partial enlarged view of an A8 region in FIG. 2.

### DESCRIPTION OF THE INVENTION

The technical solutions in some embodiments of the present disclosure will be described clearly and completely with reference to the drawings; obviously, the described embodiments are merely some but not all of the embodiments of the present disclosure. All other embodiments obtained by those ordinary skilled in the art based on the embodiments provided in the present disclosure shall be included in the protection scope of the present disclosure.

Throughout the specification and the claims, the term “comprise/include” and other forms thereof such as the third-person singular form “comprises/includes” and the present participle form “comprising/including” are construed as an open and inclusive meaning, i.e., “including, but not limited to”, unless the context requires otherwise. In the description of the specification, the terms such as “one embodiment”, “some embodiments”, “exemplary embodiments”, “example”, “specific example”, or “some examples”, etc., are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the described specific features, structures, materials, or characteristics may be included in any one or more embodiments or examples in any suitable manner.

Hereinafter, the terms “first” and “second”, etc., are only used for descriptive purposes, and cannot be construed as indicating or implying the relative importance or implicitly indicating the number of indicated technical features. Thus, a feature defined by “first” or “second”, etc., may explicitly or implicitly include one or more of this feature. In the description of the embodiments of the present disclosure, the term “a/the plurality of” or “multiple” means two or more, unless described otherwise.

In the description of some embodiments, the expressions “coupled”, “connected” and derivatives thereof may be used. The term “connected” should be understood in a broad sense. For example, the term “connected” may represent a fixed connection, a detachable connection, or a one-piece connection, or may represent a direct connection, or may represent an indirect connection through an intermediate medium.

The phrase “at least one of A, B, and C” has the same meaning as the phrase “at least one of A, B, or C”, both including the following combinations about A, B, and C: only A, only B, only C, a combination of A and B, a combination of A and C, a combination of B and C, and a combination of A, B, and C.

The phrase “A and/or B” includes the following three combinations: only A, only B, and a combination of A and B.

The use of “applicable to” or “configured to” herein indicates an open and inclusive expression, which does not exclude devices that are applicable to or configured to perform additional tasks or steps.

In addition, the use of the phrase “based on/on the basis of” is meant to be open and inclusive, since a process, step, calculation or other actions that is “based on” one or more of the stated conditions or values may, in practice, be based on additional conditions or values other than those stated.

The term such as “about”, “roughly”, or “approximately” as used herein includes a stated value and an average value within an acceptable deviation range of a particular value, where the acceptable deviation range is determined by those ordinary skilled in the art, considering the measurement(s) in question and error(s) related to the measurement(s) of a particular quantity (i.e., limitation(s) of a measurement system).

The term such as “parallel”, “perpendicular”, or “equal” as used herein includes a stated case and a case similar to the stated case. A range of the similar case is within an acceptable deviation range, where the acceptable deviation range is determined by those ordinary skilled in the art, considering the measurement(s) in question and error(s) related to the measurement(s) of a particular quantity (i.e., limitation(s) of a measurement system). For example, the term “parallel” includes absolute parallelism and approximate parallelism, where an acceptable deviation range of the approximate parallelism may be, for example, a deviation within 5°; the term “perpendicular” includes absolute perpendicularity and approximate perpendicularity, where an acceptable deviation range of the approximate perpendicularity may also be, for example, a deviation within 5°. The term “equal” includes absolute equality and approximate equality, where an acceptable deviation range of the approximate equality may be that, for example, a difference value between the equal two is less than or equal to 5% of any one of the two.

It should be understood that, when a layer or element is referred to as being on another layer or substrate, the layer or element may be directly on the another layer or substrate, or intervening layer(s) may exist between the layer or element and the another layer or substrate.

Exemplary implementations are described herein with reference to section views and/or plane views that are idealized and exemplary drawings. In the drawings, thicknesses of layers and areas of regions are enlarged for clarity. Thus, variations in shape with respect to the drawings due to, for example, manufacturing technologies and/or tolerances, may be envisaged. Therefore, the exemplary implementations should not be construed as being limited to the shapes of the regions shown herein, but should include shape deviations due to, for example, manufacturing. For example, an etched region shown in a rectangular shape generally has a curved feature. Therefore, the regions shown in the drawings are schematic in nature, and their shapes are not intended to show actual shapes of the regions in a device, and are not intended to limit the scope of the exemplary implementations.

Some embodiments of the present disclosure provide a display apparatus, and the display apparatus may be any device that displays an image, whether in motion (e.g., video) or stationary (e.g., still image) and whether text or image. Exemplarily, the display apparatus may be a television, a laptop computer, a tablet computer, a cell phone, a projector, a personal digital assistant (abbreviation: PDA), a navigator, a wearable device, an augmented reality (Augmented Reality; abbreviation: AR) device, a virtual reality (Virtual Reality; abbreviation: VR) device, or any product or component with a display function.

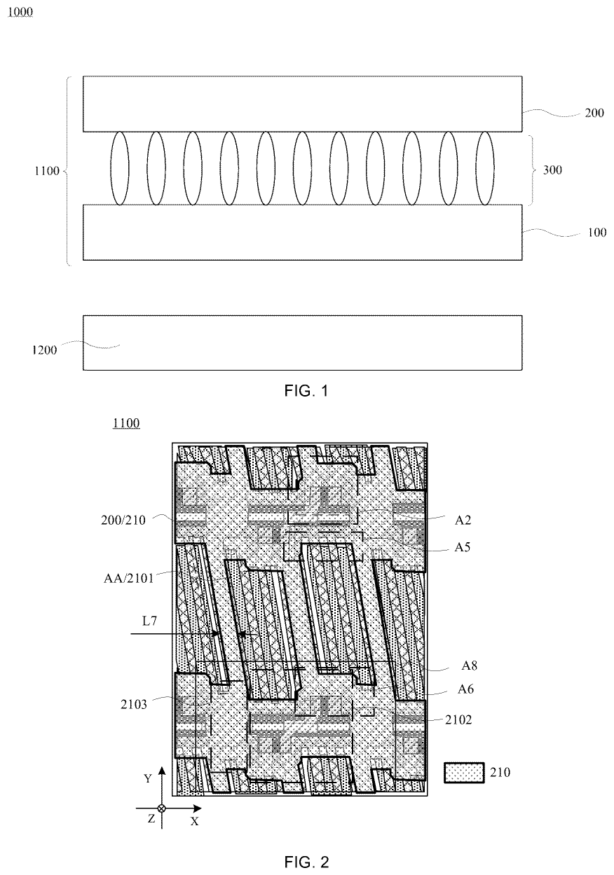

In a specific example, as shown in FIG. 1, the display apparatus 1000 may be a projector, and the display apparatus 1000 (projector) may include a display panel 1100 and a light source 1200 disposed on a side of the display panel 1100. The display panel 1100 may, for example, be a liquid crystal display panel. It can be understood that the projector may also include other structures, and exemplarily, the projector also includes an imaging module and a projection lens, etc., disposed on a side of the display panel 1100 away from the light source 1200, which will not be enumerated in the embodiments of the present disclosure.

In a case where the display panel 1100 is a liquid crystal display panel, referring to FIG. 1, the display panel 1100 may include an array substrate 100 and a color film substrate 200 that are disposed opposite to each other, and a liquid crystal layer 300 disposed between the array substrate 100 and the color film substrate 200. Of course, the display panel 1100 may also include other structures. Exemplarily, the display panel 1100 may also include a first alignment film (not shown in the figure) disposed on a side of the array substrate 100 near the liquid crystal layer 300, and a second alignment film (not shown in the figure) disposed on a side of the color film substrate 200 near the liquid crystal layer 300, etc., which will not be enumerated by the embodiments of the present disclosure.

Referring to FIG. 2, the display panel 1100 includes a plurality of sub-pixels, and each sub-pixel includes a light-emitting region AA. Exemplarily, the color film substrate 200 includes a black matrix 210 and a plurality of light-filtering portions (not shown in the figure). A plurality of openings 2101 are disposed on the black matrix 210, and each opening defines a light-emitting region AA of a sub-pixel. At least a part of each light-filtering portion of the plurality of light-filtering portions is located within an opening 2101, for passing light of a specific color through. Exemplarily, the plurality of light-filtering portions may include a red light-filtering portion for passing red light through, a green light-filtering portion for passing green light through, and a blue light-filtering portion for passing blue light through, so that the light emitted out of the color film substrate 200 may form a color picture. Herein, the aperture ratio of the black matrix 210 may be, for example, a ratio of an area of the light-emitting region AA to an area of the sub-pixel, or the aperture ratio of the black matrix 210 may be understood as a ratio of an area of light-emitting regions AA to an area of a display region of the display panel. The display region is a region on the display panel for displaying images.

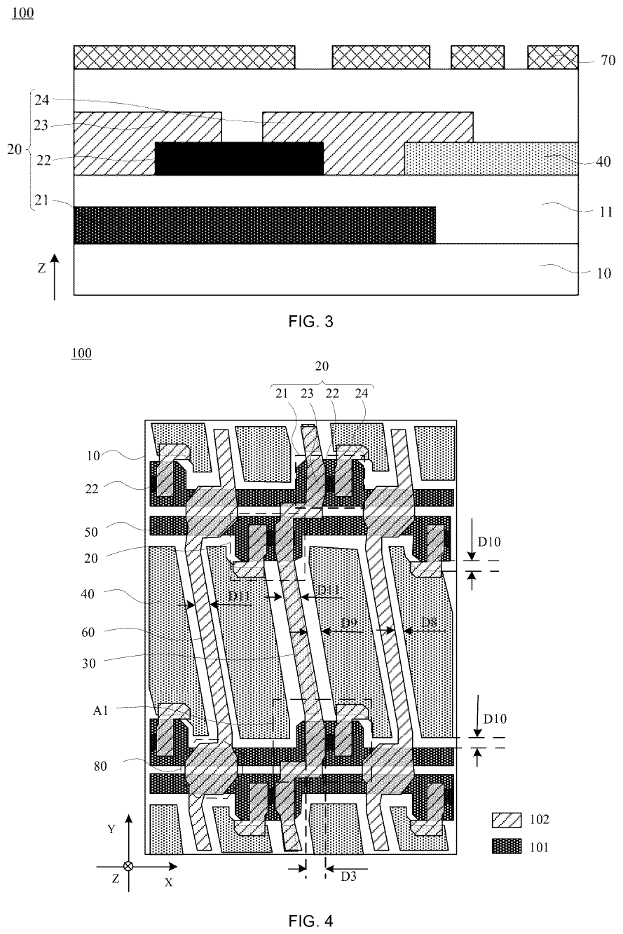

Referring to FIG. 3 and FIG. 4, the array substrate 100 may include a base 10, and a plurality of thin film transistors (Thin Film Transistor; abbreviation: TFT) 20 disposed on the base 10 and distributed in an array. Herein, FIG. 3 illustrates a cross-sectional structural view of only one thin film transistor 20, and FIG. 4 exemplarily illustrates a structure of only one thin film transistor 20 on the array substrate 100.

In a case where the display apparatus 1000 is a projector, the display panel 1100 in the projector needs to work in a high light intensity condition, and due to the light-sensitive characteristic of the thin film transistor 20, and exemplarily, a channel region of the thin film transistor 20, when being illuminated by light, generates photo-generated carriers, thereby resulting in the generation of a leakage current in the channel, and then resulting in the generation of a display abnormality in the display panel 1100. Based on this, the thin film transistor 20 needs to be light-shielded, to reduce or avoid the thin film transistor 20 from generating the leakage current.

In the related technology, a light-shielding pattern (which may be, for example, a lightproof metal block structure) is generally disposed on a side of the TFT near the base, to light-shield the TFT. However, on the one hand, this may increase the number of film layers of the display panel and increase the manufacturing process of the display panel, and as a result, lead to an increase in the thickness of the display panel and an increase in the manufacturing cost. On the other hand, an area of the light-shielding pattern is generally set to be large, which is not conducive to improving the aperture ratio and PPI of the display panel.

In order to solve the above technical problems, the embodiments of the present application provide an array substrate 100, and referring to FIG. 3, a thin film transistor 20 includes a gate pattern 21, a semiconductor pattern 22, a source pattern 23, and a drain pattern 24. The gate pattern 21 is disposed on the base 10, the semiconductor pattern 22 is disposed on a side of the gate pattern 21 away from the base 10, and the source pattern 23 and the drain pattern 24 are disposed on a same layer and are disposed on a side of the semiconductor pattern 22 away from the base 10. That is, the gate pattern 21, the semiconductor pattern 22, the source pattern 23, and the drain pattern 24 of the thin film transistor 20 are disposed in sequence in a direction away from the base 10.

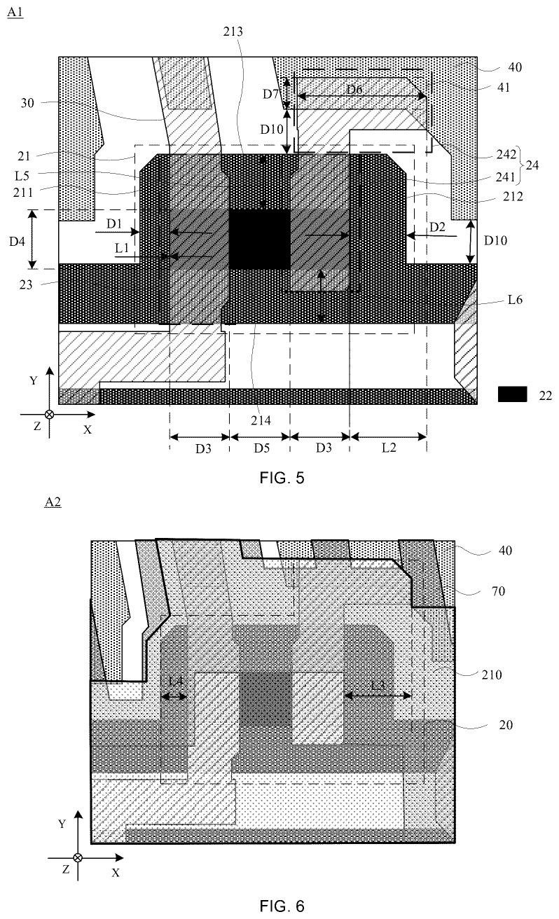

Referring to FIG. 4 and FIG. 5, the gate pattern 21 includes a first sidewall 211 and a second sidewall 212 that are disposed opposite to each other along a first direction X. The first sidewall 211 (compared to the second sidewall 212) is near the source pattern 23, and the second sidewall 212 (compared to the first sidewall 211) is near the drain pattern 24. Herein, the source pattern 23 and the drain pattern 24 are disposed at intervals along the first direction X.

Exemplarily, referring to FIG. 3, a gate insulating layer (Gate Insulator; abbreviation: GI) 11 is also included between the semiconductor pattern 22 and the gate pattern 21. The semiconductor pattern 22 is disposed on a side of the gate insulating layer 11 away from the base 10, and for example, the semiconductor pattern 22 contacts with the gate pattern 21 directly. The gate insulating layer 11 may separate the semiconductor pattern 22 from the gate pattern 21, so as to form an electrical insulation between the semiconductor pattern 22 and the gate pattern 21, and avoid a short circuit between the semiconductor pattern 22 and the gate pattern 21. The gate insulating layer 11 may, for example, be a continuous whole-layer structure.

Herein, in the embodiments of the present disclosure, “disposed on a same layer” means that a film layer for forming a specific pattern is formed by using a same film-forming process, and then a layer structure is formed by using a same mask plate by a one-shot patterning process. Depending on different specific patterns, the one-shot patterning process may include multiple exposure, development, or etching processes, and the specific patterns in the formed layer structure may be continuous or discontinuous, and these specific patterns may also be at different heights or have different thicknesses. Exemplarily, referring to FIG. 3 and FIG. 5, the source pattern 23 and the drain pattern 24 are disposed on the same layer, which may mean that the source pattern 23 and the drain pattern 24 are manufactured and formed by using a same material and a same stage, on a surface away from the base 10 which is formed by the gate insulating layer 11 and the semiconductor pattern 22. For example, the source pattern 23 and the drain pattern 24 may be disposed on a surface on which the gate insulating layer 11 and the semiconductor pattern 22 are formed together.

Referring to FIG. 3, FIG. 4, and FIG. 5, an orthographic projection of the semiconductor pattern 22 on the base 10 is located within a range of an orthographic projection of the gate pattern 21 on the base 10 (not shown in the figures), and a boundary of the semiconductor pattern 22 has an interval a boundary of the gate pattern 21. That is, the gate pattern 21 may completely shield the semiconductor pattern 22 from a side (lower side) of the semiconductor pattern 22 near the base 10, so that the gate pattern 21 may be used to shield the semiconductor pattern 22 (e.g., shield light from the light source), and thus there is no need to dispose a lighting-shielding pattern specifically on a side of the thin film transistor 20 near the base 10, which is conducive to reducing the thickness of the array substrate 100, and conducive to the light and thin design of the display panel, and may reduce the manufacturing process of the array substrate 100 and reduce the manufacturing cost of the array substrate 100.

Exemplarily, the gate pattern 21 may be manufactured and formed by using a lightproof metal material (such as copper or copper alloy), and the thickness of the gate pattern 21 may be flexibly set according to an actual demand (such as according to a maximum brightness of light emitted from the light source), to reduce the light transmittance of the gate pattern 21. This reduces the risk of light passing through the gate pattern 21 and illuminating onto the semiconductor pattern 22, prevents the thin film transistor 20 from generating the leakage current, and improves the stability of the thin film transistor 20.

It can be understood that, as shown in FIG. 4 and FIG. 5, the array substrate 100 also includes a data line 30 disposed on the same layer as the source pattern 23 and the drain pattern 24, and the data line 30 is electrically connected to the source pattern 23, or in other words, the data line 30 and the source pattern 23 are shown as a continuous pattern in an actual layout, and it is only for the sake of convenience in description that the data line 30 and the source pattern 23 are artificially divided into two parts, which are described respectively. Exemplarily, the film layer in which the source pattern 23 and the drain pattern 24 are located is taken as a second conductive layer 102, and the data line 30 is also located on the second conductive layer 102, and in the embodiments of the present disclosure, the source pattern 23 refers to a part of the second conductive layer 102, which is used to transmit data signals, and an orthographic projection of which on the base 10 is located within a range of an orthographic projection of the gate pattern 21 on the base 10; and the data line 30 refers to a part, which is connected to the source pattern 23, and an orthographic projection of which on the base 10 does not overlap with the orthographic projection of the gate pattern 21 on the base 10.

The source pattern 23 and the drain pattern 24 are disposed at intervals along the first direction X, and the source pattern 23 and the drain pattern 24 are electrically connected to two ends of the semiconductor pattern 22 along the first direction X, respectively. Exemplarily, the source pattern 23 is electrically connected to an end of the semiconductor pattern 22 near the first sidewall 211, and the drain pattern 24 is electrically connected to an end of the semiconductor pattern 22 near the second sidewall 212. Moreover, along the first direction X, an interval L1 between an end of the source pattern 23 near the first sidewall 211 (hereinafter referred to as a first end) and the semiconductor pattern 22 is smaller than an interval L2 between an end of the drain pattern 24 near the second sidewall 212 (hereinafter referred to as a second end) and the semiconductor pattern 22, i.e., L1<L2.

Herein, “along the first direction X, an interval L1 between an end of the source pattern 23 near the first sidewall 211 and the semiconductor pattern 22” may be understood as: an interval between an orthographic projection of an end of the source pattern 23 near the first sidewall 211 on the base 10, and an orthographic projection of the semiconductor pattern 22 on the base 10. In the embodiments of the present disclosure, the similar expression is used when describing an interval between any two structures; that is, when describing an interval between two structures (A and B) located on different film layers, it can be understood as an interval between an orthographic projection of A on the base and an orthographic projection of B on the base. In other words, in the embodiments of the present disclosure, in a case where A and B are located on different film layers, “an interval between A and B” refers to an interval between an orthographic projection of A on the base and an orthographic projection of B on the base. In order to simplify the expression, the similar expression is used in the embodiments of the present application.

Exemplarily, as shown in FIG. 4, a boundary of the source pattern 23 near the first sidewall 211 is flush with a boundary of the semiconductor pattern 22 near the first sidewall 211; that is, the interval L1 between a first end of the source pattern 23 and the semiconductor pattern 22 is 0 μm. An end portion of the drain pattern 24 near the second sidewall 212 is at least partially located on a side of the second sidewall 212 away from the first sidewall 211; that is, the interval L2 between a second end of the drain pattern 24 and the semiconductor pattern 22 is larger than Oum. In other words, a left boundary of the source pattern 23 is roughly flush with a left boundary of the semiconductor pattern 22, and a right boundary of the drain pattern 24 is further away from the source pattern 23, compared to a right boundary of the semiconductor pattern 22.

It should be noted that the left boundary of the source pattern 23 is roughly flush with the left boundary of the semiconductor pattern 22, which may be understood as that the two are flush with each other when being designed, but due to factors such as measurement errors and manufacturing process errors (e.g., alignment precision and manufacturing precision), etc., there may be an interval between the left boundary of the source pattern 23 and the left boundary of the semiconductor pattern 22. Exemplarily, if L1<M, it may be considered as that the left boundary of the source pattern 23 is roughly flush with the left boundary of the semiconductor pattern 22, and for example, M may be 0.5 μm, 1 μm, or 2 μm, etc. Moreover, in other embodiments of the present disclosure, the expression that the two components are roughly flush, considering the process errors and measurement errors or the like, may be understood as that there may be a certain interval between the two components, and the interval is within an acceptable deviation range. In some embodiments, continuing to refer to FIG. 5, the drain pattern 24 includes a first sub-portion 241 and a second sub-portion 242. The first sub-portion 241 extends along a second direction Y, and is electrically connected to the semiconductor pattern 22. The second direction Y intersects with the first direction X. Exemplarily, the second direction Y and the first direction X are perpendicular to each other. An orthographic projection of the first sub-portion 241 on the base 10 is located within a range of an orthographic projection of the gate pattern 21 on the base 10. The second sub-portion 242 is connected with the first sub-portion 241, and along the first direction X, an end portion of the second sub-portion 242 away from the first sub-portion 241 (hereinafter referred to as a third end) is flush with the second sidewall 212, or extends out of the second sidewall 212. In the embodiments of the present disclosure, as shown in FIG. 5, it is described by taking an example in which the third end of the second sub-portion 242 extends out of the second sidewall 212.

It can be understood that, as shown in FIG. 6, the color film substrate 200 includes the black matrix (Black Matrix; abbreviation: BM) 210, and the black matrix 210 covers the thin film transistor 20 on the array substrate 100, to reduce the reflection of ambient light by the thin film transistor 20, and reduce the risk of light illumination onto the semiconductor pattern 22 from a side of the thin film transistor 20 away from the base 10. Accordingly, the black matrix 210 covers at least a boundary of the thin film transistor 20, that is, an orthographic projection of the black matrix 210 on the base 10, covers an orthographic projection of the drain pattern 24 on the base 10, and exemplarily, a boundary of the orthographic projection of the black matrix 210 on the base 10 is flush with a boundary of the orthographic projection of the drain pattern 24 on the base 10, or has an interval with a boundary of the orthographic projection of the drain pattern 24 on the base 10, which may reduce the risk of oblique light (light that has an angle with a third direction Z) emitting into the thin film transistor 20.

Based on this, referring to FIG. 5 and FIG. 6, in a case where the size of the drain pattern 24 (e.g., the size along the first direction X) is determined, the end portion (the third end) of the drain pattern 24 near the second sidewall 212 is flush with the second sidewall 212, or at least partially located on a side of the second sidewall 212 away from the first sidewall 211, i.e., the second sidewall 212 of the gate pattern 21 is nearer the drain pattern 21, compared to the third end of the drain pattern 24. In this way, without additionally increasing the size of the black matrix 210, the black matrix 210 may cover both the drain pattern 24 and the second sidewall 212 of the gate pattern 21, which is conducive to reducing the size of the black matrix 210, and then improving the aperture ratio of the opening 2101 on the black matrix 210, and improving the light extraction efficiency of the display panel 1100. It can be understood that if the second sidewall 212 of the gate pattern 21 is further away from the semiconductor pattern compared to the third end of the drain pattern 24, the black matrix 210 needs to increase the size of the right side (near the second sidewall 212), so that an orthographic projection of the black matrix 210 on the base 10 can completely cover the thin film transistor 20 (the second sidewall 212). This is not conducive to improving the aperture ratio of the display panel 1100.

Referring to FIG. 5 and FIG. 6, based on the difference in the sizes of the source pattern 23 and the drain pattern 24 along the first direction X (along the first direction X, the third end of the drain pattern 24 extends out of the boundary of the semiconductor pattern 22, and the left boundary of the source pattern 23 is roughly flush with the left boundary of the semiconductor pattern 22).

In the orthographic projection on the base 10 and in a part of the black matrix 210 for covering the thin film transistor 20, a size L3 of a part (along the first direction X) located on a side (right side) of the semiconductor pattern 22 near the second sidewall 212, is larger than a size L4 of a part (along the first direction X) of the black matrix 210 located on a side (left side) of the semiconductor pattern 22 near the first sidewall 211. In this way, it is conducive to the black matrix 210 to cover the source pattern 23 and the drain pattern 24. Herein, L3 may also be considered to be an interval along the first direction X between the right boundary of the semiconductor pattern 22 and the third end of the drain pattern 24, and L4 may also be considered to be an interval along the first direction X between the left boundary of the semiconductor pattern 22 and the first sidewall 211 of the gate pattern 21.

In the embodiments of the present disclosure, as shown in FIG. 5, an interval D1 between the semiconductor pattern 22 and the first sidewall 211 is smaller than an interval D2 between the semiconductor pattern 22 and the second sidewall 212. That is, a width of a part of the gate pattern 21 located on the right side of the semiconductor pattern 22 is larger than a width of a part of the gate pattern 21 located on the left side of the semiconductor pattern 22. On the one hand, the first sidewall 211 is near the light-emitting region of the array substrate 100, which reduces the interval between the first sidewall 211 and the semiconductor pattern 22, which is conducive to improving the area of the light-emitting region, and then improving the aperture ratio of the array substrate 100. On the other hand, it is conducive to reducing a width of a side of the gate pattern 21 near the source pattern 23, and then reducing the area of the gate pattern 21, and reducing the size of the thin film transistor 20, and further reducing the area of the black matrix 210, which is conducive to improving the aperture ratio of the display panel, and then improving the light transmittance of the display panel 1100, and conducive to the display panel to achieve a high PPI.

In some embodiments, as shown in FIG. 5, an interval between the semiconductor pattern 22 and the first sidewall 211 is D1, an interval between the semiconductor pattern 22 and the second sidewall 212 is D2, and a ratio of D1 to D2 is 0.5 to 0.6. Based on this, the interval along the first direction X between the first sidewall 211 and the semiconductor pattern 22 may be minimized, on the premise of ensuring that the gate pattern 21 shields the semiconductor pattern 22, that is, a width of a part of the gate pattern 21 located on the left side of the semiconductor pattern 22 may be minimized, thereby reducing the area of the orthographic projection of the thin film transistor 20 on the base 10, and improving the aperture ratio of the display panel. Exemplarily, the ratio of D1 to D2 may be 0.5, 0.55, 0.58, or 0.6, etc., which will not be enumerated in the embodiments of the present disclosure.

Exemplarily, the interval D1 between the semiconductor pattern 22 and the first sidewall 211 may be 1.3 μm to 1.7 μm; and/or, the interval D2 between the semiconductor pattern 22 and the second sidewall 212 may be 2.5 μm to 3.0 μm. Exemplarily, the interval D1 between the semiconductor pattern 22 and the first sidewall 211 may be 1.3 μm, 1.5 μm, or 1.7 μm, etc., and the interval D2 between the semiconductor pattern 22 and the second sidewall 212 may be 2.5 μm, 2.7 μm, 2.75 μm, or 3.0 μm, etc., which will not be enumerated in the embodiments of the present disclosure. In this way, on the premise of ensuring the effect of the gate pattern 21 shielding the semiconductor pattern 22, the size of the gate pattern 21 along the first direction X may be minimized, the area of the thin film transistor 20 may be reduced, and the aperture ratio of the array substrate 100 may be improved. Also, the risk of scattered light within the liquid crystal layer 300 being emitted into the semiconductor pattern 22 may be reduced.

In some embodiments, referring to FIG. 5, the gate pattern 21 also includes a third sidewall 213 and a fourth sidewall 214 that are disposed opposite to each other along the second direction Y. An interval L5 between the semiconductor pattern 22 and the third sidewall 213, an interval L6 between the semiconductor pattern 22 and the fourth sidewall 214, and an interval D2 between the semiconductor pattern 22 and the second sidewall 212 are roughly equal; i.e., L5=L6=D2. That is, as shown in FIG. 5, widths of parts of the gate pattern 21 located on the upper side, the lower side, and the right side of the semiconductor pattern 22 are equal. It is conducive to improving the shielded widths of the gate pattern 21 to two sides (the upper side and the lower side) of the semiconductor pattern 22 along the second direction Y, and reducing the risk of light emitting into the semiconductor pattern 22 from the gate pattern 21 on two sides along the second direction Y, so that the risk of generating the leakage current in the thin film transistor 20 may be reduced, and the risk of crosstalk occurring between the source pattern 23 and the drain pattern 24 may be reduced. Herein, considering factors such as the process errors and measurement errors, roughly equal means exactly equal or having a certain deviation, the aforementioned deviation is within an acceptable deviation range, and the acceptable deviation range may be, for example, 5%, 6%, or other specific values. Exemplarily, taking the interval D2 between the semiconductor pattern 22 and the second sidewall 212 as a reference, L5 and L6 may be (1±5%) D2. Similarly, when any two values are described as equal in the present disclosure, it may be understood as that the two are exactly equal, or the two have a deviation within an acceptable range.

It can be understood that during the manufacturing process of the thin film transistor 20, the process management and control capability in the first direction X of the respective patterns (the gate pattern 21, the semiconductor pattern 22, the source pattern 23, and the drain pattern 24) of the thin film transistor 20 is greater than the process management and control capability in the second direction Y thereof. That is, the size precision along the first direction X of the respective patterns of the thin film transistor 20 is greater than the size precision along the second direction Y. Exemplarily, taking the gate pattern 21 as an example, compared to the design size of the gate pattern 21, the size difference ratio (error ratio or deviation range) along the first direction X of the gate pattern 21 obtained by the actual manufacturing is smaller than the size difference ratio along the second direction Y. Based on this, the interval L5 between the semiconductor pattern 22 and the third sidewall 213, and the interval L6 between the semiconductor pattern 22 and the fourth sidewall 214 are greater than the interval D1 between the semiconductor pattern 22 and the first sidewall 211, which is conducive to improving the shielded width of the gate pattern 21 to the semiconductor pattern 22 in the second direction Y, thereby reducing the risk of light emitted from a side of the base 10 into the semiconductor pattern 22.

Exemplarily, the interval L5 between the semiconductor pattern 22 and the third sidewall 213 and the interval L6 between the semiconductor pattern 22 and the fourth sidewall 214 are each equal to the interval D2 between the semiconductor pattern 22 and the second sidewall 212, and both are 2.5 μm to 3.0 μm.

In some embodiments, referring to FIG. 5, along the first direction X, the size of the overlapped part of the source pattern 23 and the semiconductor pattern 22, and the size of the overlapped part of the drain pattern 24 and the semiconductor pattern 22 are roughly equal (both are marked as D3), which is conducive to improving the uniformity of the source pattern 23 and the drain pattern 24. Moreover, the size D4 of the semiconductor pattern 22 along the second direction Y is larger than the interval D5 between the source pattern 23 and the drain pattern 24. On the one hand, this is conducive to reducing the area of the semiconductor pattern 22, reducing the area of the orthographic projection of the thin film transistor 20 on the base, and improving the aperture ratio of the display panel 1100. On the other hand, the width-to-length ratio of the channel between the source pattern 23 and the drain pattern 24 is greater than 1, which is conducive to improving the saturated current of the thin film transistor 20, and improving the performance of the thin film transistor 20.

In some embodiments, along the first direction X, the sizes of the overlapped parts of the source pattern 23 and the drain pattern 24 with the semiconductor pattern 22 are D3, and D3 is 3 μm to 3.85 μm. In a case where D3 is 3 μm to 3.85 μm, the stability of the connection of the source pattern 23 and the drain pattern 24 with the semiconductor pattern 22, and the aperture ratio of the display panel may be balanced. Exemplarily, D3 may be 3 μm, 3.5 μm, or 3.85 μm, etc., which will not be enumerated in the embodiments of the present disclosure.

It can be understood that if the value of D3 is too small (e.g., less than 3 μm), the contacting area of the source pattern 23 and the drain pattern 24 with the semiconductor pattern 22 is small, and the problem of poor contacting or high resistance of the source pattern 23 and the drain pattern 24 with the semiconductor pattern 22 may occur; and if the value of D3 is too large (e.g., greater than 3.85 μm), it is not conducive to reducing the size of the thin film transistor 20, and not conducive to improving the aperture ratio of the display panel.

As shown in FIG. 5, in a case where the boundary of the source pattern 23 near the first sidewall 211 and the boundary of the semiconductor pattern 22 near the first sidewall 211 are roughly flush, the size D3 of the overlapped part of the source pattern 23 with the semiconductor pattern 22 along the first direction X described above may also be understood as: the width of the source pattern 23 along the first direction X. In a case where the first sub-portion 241 of the drain pattern 24 is roughly flush with the boundary of the semiconductor pattern 22 near the second sidewall 212, the size D3 of the overlapped part of the drain pattern 24 with the semiconductor pattern 22 along the first direction X may also be understood as: the width of the first sub-portion 241 along the first direction X.

The size D4 of the semiconductor pattern 22 along the second direction Y is D4, and D4 is 3 μm to 3.7 μm. In a case where D4 is 3 μm to 3.7 μm, the performance of the thin film transistor 20 and the aperture ratio of the display panel may be balanced. Exemplarily, the size D4 of the semiconductor pattern 22 along the second direction Y may be 3 μm, 3.4 μm, or 3.7 μm, etc., which will not be enumerated in the embodiments of the present disclosure. It can be understood that if the value of D4 is too small (e.g., less than 3 μm), the width of the semiconductor pattern 22 is too small, and the saturated current of the thin film transistor 20 is small, which is not conducive to improving the performance of the thin film transistor 20; and if the value of D4 is too large (e.g., greater than 3.7 μm), it is not conducive to reducing the size of the thin film transistor 20, and not conducive to improving the aperture ratio of the display panel.

Along the first direction X, the interval between the source pattern 23 and the drain pattern 24 is D5, and D5 is 1.8 μm to 2.4 μm. In this way, it is conducive to improving the width-to-length ratio of the channel of the thin-film transistor, thereby improving the performance of the thin film transistor 20, and it is conducive to reducing the overall size of the thin film transistor 20, and it may reduce the risk of signal crosstalk occurring between the source pattern 23 and the drain pattern 24. Exemplarily, the interval D5 between the source pattern 23 and the drain pattern 24 may be 1.8 μm, 2.0 μm, 2.28 μm, or 2.4 μm, etc., which will not be enumerated in the embodiments of the present disclosure.

It can be understood that, if the value of D5 is too small (e.g., less than 1.8 μm), the signal crosstalk may occur between the source pattern 23 and the drain pattern 24. If the value of D5 is too large (e.g., greater than 2.4 μm), the length of the width of the channel between the source pattern 23 and the drain pattern 24 is small, which is not conducive to improving the performance of the thin film transistor 20, and not conducive to reducing the size of the thin film transistor 20, and not conducive to improving the aperture ratio of the display panel.

In some embodiments, referring to FIG. 3 and FIG. 4, the array substrate 100 also includes a pixel electrode 40. The pixel electrode 40 is configured to be electrically connected to the drain pattern 24, and used to form an electric field with a common electrode. The pixel electrode 40 is located on a same film layer as the semiconductor pattern 22, and an orthographic projection of the pixel electrode 40 on the base 10 has an interval with an orthographic projection of the gate pattern 21 on the base 10. That is, the orthographic projection of the pixel electrode 40 on the base 10 and the orthographic projection of the semiconductor pattern 22 on the base 10 have an interval, so that the risk of generating a parasitic capacitance between the pixel electrode 40 and the gate pattern 21 may be reduced, and the bad effect of the gate pattern 21 on the pixel electrode 40 may be reduced. Although the pixel electrode 40 and the semiconductor pattern 22 are on the same film layer, there is an interval between the pixel electrode 40 and the semiconductor pattern 22, so the electrical insulation may be maintained between the pixel electrode 40 and the semiconductor pattern 22, thereby avoiding the generation of signal interference between them.

Exemplarily, referring to FIG. 4, the array substrate 100 also includes a gate line 50 disposed on a same layer as the gate pattern 21, and the gate line 50 is electrically connected to the gate pattern 21 and configured to transmit a scanning signal to the gate pattern 21. The orthographic projection of the pixel electrode 40 on the base 10 does not overlap (has an interval) with an orthographic projection of the gate line 50 on the base 10, so that the risk of generating the parasitic capacitance between the pixel electrode 40 and the gate line 50 may be reduced, and the bad effect of the gate pattern 21 on the pixel electrode 40 may be reduced. In the embodiments of the present disclosure, a film layer in which the gate pattern 21 and the gate line 50 are located may be referred to as the first conductive layer 101, and the orthographic projection of the first conductive layer 101 on the base 10 does not overlap with the orthographic projection of the pixel electrode 40 on the base 10.

It can be understood that, “the pixel electrode 40 and the semiconductor pattern 22 are located on the same film layer”, which means that: there is no other film layer between the pixel electrode 40 and the semiconductor pattern 22 along a direction perpendicular to the base 10 (the third direction Z), and in the manufacturing process of the array substrate, the pixel electrode 40 and the semiconductor pattern 22 are formed on a surface of the same film layer, and the pixel electrode 40 and the semiconductor pattern 22 are formed by using two stages separately and independently. Exemplarily, the pixel electrode 40 and the semiconductor pattern 22 are formed on a surface of the gate insulating layer 11 away from the base 10 (directly contact with a surface of the gate insulating layer 11 away from the base 10). Exemplarily, in the manufacturing process of the array substrate, the semiconductor pattern 22 may be first manufactured and formed, and then the pixel electrode 40 may be manufactured and formed.

Referring to FIG. 4, in a case where the array substrate 100 includes the gate lines 50, an interval between the pixel electrode 40 and the gate pattern 21, and an interval between the pixel electrode 40 and the gate line 50 are equal and both are D10, along the second direction Y. That is, the pixel electrode 40 is disposed at equal intervals with the gate pattern 21 and the gate line 50. In this way, the aggregation of the charge in a region of the pixel electrode 40 near the gate pattern 21 may be avoided, so that the charge is uniformly distributed at the edge of the pixel electrode 40 near the gate pattern 21 and the gate line 50, thereby improving the uniformity of the electric field formed between the pixel electrode 40 and the common electrode 70.

In some embodiments, an interval D10 between the pixel electrode 40 and the gate pattern 21 and an interval D10 between the pixel electrode 40 and the gate line 50 are both 2.0 μm to 2.4 μm. This not only may reduce the parasitic capacitance of the pixel electrode 40 with the gate pattern 21 and the gate line 50, but also maximize the area of the pixel electrode 40. Exemplarily, the interval D10 between the pixel electrode 40 and the gate pattern 21 may be 2.0 μm, 2.2 μm, or 2.4 μm.

Referring to FIG. 4 and FIG. 5, the pixel electrode 40 includes a lap joint portion 41, and the lap joint portion 41 is electrically connected to the drain pattern 24. Also, a size D6 of the lap joint portion 41 along the first direction X is larger than a size D7 of the lap joint portion 41 along the second direction Y, which is conducive to reducing the size of the drain pattern 24 (the second sub-portion 242) along the second direction Y, thereby reducing the size of the black matrix along the second direction Y, increasing the area of the opening (the display region) on the black matrix, and improving the aperture ratio of the display panel. It can be understood that the lap joint portion 41 is a part on the pixel electrode 40, which contacts with the drain pattern 24 mutually.

In some embodiments, the size of the lap joint portion 41 along the first direction X is D6, and D6 is 6.1 μm to 6.5 μm. In this way, it is conducive to improving the contacting area between the lap joint portion 41 and the drain pattern 24, and ensuring the stability of the connection between the lap joint portion 41 and the drain pattern 24. Exemplarily, the size of the lap joint portion 41 along the first direction X is D6, which may be 6.1 μm, 6.3 μm, 6.4 μm, or 6.5 μm, etc., which will not be enumerated in the embodiments of the present disclosure. It can be understood that if the value of D6 is too small (e.g., less than 6.1 μm), the contacting area is small and the resistance is large between the drain pattern 24 and the lap joint portion 41, which is not conducive to the signal transmission between the drain pattern 24 and the lap joint portion 41. If the value of D6 is too large (e.g., greater than 6.5 μm), the size of the drain pattern 24 along the first direction X is too long, which is not conducive to improving the aperture ratio of the display panel.

A size of the lap joint portion 41 along the second direction Y is D7, and D7 is 1.4 μm to 1.8 μm. In this way, the size of the lap joint portion 41 along the second direction Y may be minimized and the aperture ratio of the display panel may be increased, in a case of ensuring a stable connection between the lap joint portion 41 and the drain pattern 24. Exemplarily, the size of the lap joint portion 41 along the second direction Y is D7, which may be 1.4 μm, 1.6 μm, or 1.8 μm, etc., which will not be enumerated in the embodiments of the present disclosure.

It can be understood that if the value of D7 is too small (e.g., less than 1.4 μm), it may lead to a failure of the connection between the drain pattern 24 and the lap joint portion 41, which is not conducive to the signal transmission between the drain pattern 24 and the lap joint portion 41. If the value of D7 is too large (e.g., greater than 1.8 μm), it may increase the size of the black matrix along the second direction Y, which is not conducive to improving the aperture ratio of the display panel.

In some embodiments, referring to FIG. 4, the array substrate 100 also includes a plurality of data lines 30 and a plurality of common voltage signal lines 60. The plurality of data lines 30 and the plurality of common voltage signal lines 60 are arranged in alternating lines along the first direction X. Exemplarily, a common voltage signal line 60 is included between every two adjacent data lines 30, and a data line is included between every two adjacent common voltage signal lines 60. The plurality of data lines 30 and the plurality of common voltage signal lines 60 are disposed on a same layer as the source pattern 23 and the drain pattern 24. That is, the data lines 30, the common voltage signal lines 60, the source pattern 23 and the drain pattern 24 are manufactured and formed by using a same material and a same process synchronously, and are all located in a third conductive layer. It can be understood that only one data line 30 and one common voltage signal line 60 are shown in FIG. 4 exemplarily.

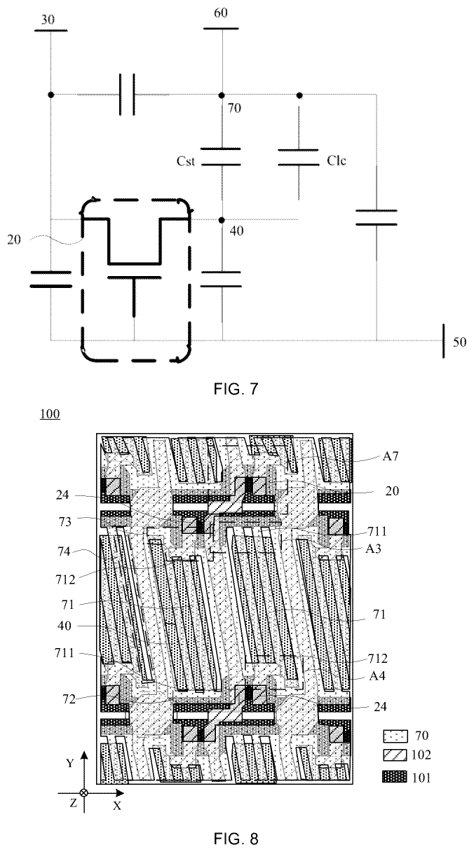

The data line 30 is configured to transmit a data signal, the data signal may, for example, be a pulse signal; and the common voltage signal line 60 is configured to transmit a common voltage signal, and the common voltage signal may, for example, be a constant voltage signal. Referring to FIG. 7, the thin film transistor 20 is configured to be turned on under the control of a scanning signal from the gate line 50, to transmit the data signal from the data line 30 to the pixel electrode 40 (node 40).

Referring to FIG. 4, in an orthographic projection on the base 10, an interval D8 between the pixel electrode 40 and the common voltage signal line 60 (along the first direction X) is smaller than an interval D9 between the pixel electrode 40 and the data line 30 (along the first direction X). In this way, on the one hand, the area of the pixel electrode 40 may be increased, which is conducive to improving the aperture ratio of the display panel 1100, and on the other hand, the risk of generating signal interference between the pixel electrode 40 and the data line 30 may be reduced.

It can be understood that, referring to FIG. 4 and FIG. 7, a first parasitic capacitance Clc may be generated between the common voltage signal line 60 and the pixel electrode 40, and since the constant voltage signal is transmitted on the common voltage signal line 60 and the first parasitic capacitance Clc has no interfering effect on the signal of the pixel electrode 40, the interval D8 between the pixel electrode 40 and the common voltage signal line 60 (along the first direction X) may be reduced, which is conducive to increasing the area of the pixel electrode 40. An interval D9 between the pixel electrode 40 and the data line 30 is large, which may reduce or avoid the parasitic capacitance that will be generated between the pixel electrode 40 and the data line 30, and then avoid signal interference from the data line 30 to the pixel electrode 40. If the parasitic capacitance is generated between the pixel electrode 40 and the data line 30, the data signal (pulse signal) transmitted on the data line 30 will, due to voltage fluctuations, cause fluctuations in the voltage of the pixel electrode 40, which results in fluctuations in the light transmittance of the light-emitting region, which is not conducive to displaying images by the display panel.

In some embodiments, as shown in FIG. 4, an interval D8 between the pixel electrode 40 and the common voltage signal line 60 along the first direction X is 2.4 μm to 2.8 μm. The interval D8 between the pixel electrode 40 and the common voltage signal line 60 along the first direction X may be minimized, thereby maximizing the area of the pixel electrode 40, and improving the aperture ratio of the display panel. Exemplarily, the interval D8 between the pixel electrode 40 and the common voltage signal line 60 may be 2.4 μm, 2.6 μm, or 2.8 μm, etc., which will not be enumerated in the embodiments of the present disclosure.

An interval D9 between the pixel electrode 40 and the data line 30 along the first direction X is 3.0 μm to 3.4 μm. This not only reduces the risk of forming a parasitic capacitance between the pixel electrode 40 and the data line 30, but also minimizes the interval between the pixel electrode 40 and the data line 30, which is conducive to improving the area of the pixel electrode 40. Exemplarily, the interval D9 between the pixel electrode 40 and the data line 30 may be 3.0 μm, 3.2 μm, or 3.4 μm, etc., which will not be enumerated in the embodiments of the present disclosure.

In some embodiments, as shown in FIG. 4, the size of the data line 30 along the first direction X and the size of the common voltage signal line 60 along the first direction X are equal and both are D11. The data line 30 is electrically connected to the source pattern 23, and exemplarily, the size D11 of the data line 30 along the first direction X is smaller than the size D3 of the overlapped part of the source pattern 23 with the semiconductor pattern 22 along the first direction X, i.e., D11<D3. In this way, it is conducive to reducing the sizes of the data line 30 and the common voltage signal line 60 along the first direction X, thereby reducing a size of a part of the black matrix 210 which covers the data line 30 and the common voltage signal line 60, along the first direction X, and then increasing the area proportion of the opening 2101 and improving the aperture ratio of the display panel.

Exemplarily, the sizes of the data line 30 and the common voltage signal line 60 along the first direction X are D11, and D11 is 2.4 μm to 2.8 μm. In this way, it may minimize the sizes of the data line 30 and the common voltage signal line 60 along the first direction X, and maximally improve the aperture ratio of the display panel, in a case of ensuring that the resistances of the data line 30 and the common voltage signal line 60 is not increased significantly. Exemplarily, the sizes of the data line 30 and the common voltage signal line 60 along the first direction X are D11, which may be 2.4 μm, 2.6 μm, or 2.8 μm, etc., which will not be enumerated in the embodiments of the present disclosure.

It can be understood that if the value of D11 is too small (e.g., less than 2.4 μm), it may result in larger resistance values of the data line 30 and the common voltage signal line 60, which is not conducive to the data line 30 for transmitting the data signal, and not conducive to the common voltage signal line 60 for transmitting the common voltage signal. If the value of D11 is too large (e.g., greater than 2.8 μm), and in a case where the PPI of the array substrate is constant, the size of the pixel electrode 40 along the first direction X may be compressed, i.e., the size of the pixel electrode 40 along the first direction X may be small, which is not conducive to improving the aperture ratio of the display panel.

Exemplarily, as shown in FIG. 2, the size of the part of the black matrix 210 for covering the data line 30 and the common voltage signal line 60 is L 7 along the first direction X, and L7 may be 4.8 μm to 5.2 μm. In this way, the black matrix 210 may completely shield the data line 30 and the common voltage signal line 60, and light emitted from a front side (a side away from the base) of the display panel obliquely towards the data line 30 and the common voltage signal line 60 may be reduced, and the risk of light emitted by the data line 30 and the common voltage signal line 60 being emitted out of the front side of the display panel may be reduced. Exemplarily, L7 may be 4.8 μm, 5.0 μm, or 5.2 μm, etc., which will not be enumerated in the embodiments of the present disclosure.

It can be understood that if the value of L7 is too small (e.g., less than 4.8 μm), the black matrix 210 is less effective in shielding the data line 30 and the common voltage signal line 60, and a part of light reflected from the data line 30 and the common voltage signal line 60 may be emitted out of the display panel, resulting in the poor display. If the value of L7 is too large (e.g., greater than 5.2 μm), the area of the black matrix 210 may increase, which is not conducive to improving the area proportion of the opening 2101, and not conducive to improving the aperture ratio of the display panel 1100. Based on this, in the embodiments of the present disclosure, the size of the part of the black matrix 210 for covering the data line 30 and the common voltage signal line 60 is 4.8 μm to 5.2 μm along the first direction X.

In some embodiments, an interval D10 between the pixel electrode 40 and the gate pattern 21 is smaller than the interval D8 between the pixel electrode 40 and the common voltage signal line 60, which is conducive to further increasing the size of the pixel electrode 40 along the second direction Y and increasing the aperture ratio of the display panel.

In some embodiments, referring to FIG. 3, the array substrate 100 also includes a common electrode 70. The common electrode 70 is located on a side of the source pattern 23 and the drain pattern 24 away from the base 10. Referring to FIG. 8, the common electrode 70 includes at least one electrode stripe 71 extending along the second direction Y. An electric field may be formed between the common electrode 70 and the pixel electrode 40, the liquid crystal molecules within the liquid crystal layer 300 are deflected under the effect of the upper electric field, thereby adjusting the light transmittance of the light-emitting region AA, to achieve the display effect of different gray levels. Exemplarily, as shown in FIG. 8, within a light-emitting region AA, the common electrode 70 includes two electrode stripes 71 arranged at an interval along the first direction X, and the two electrode stripes 71 are conducive to improving the aperture ratio and the light-emitting efficiency of the display panel 1100.

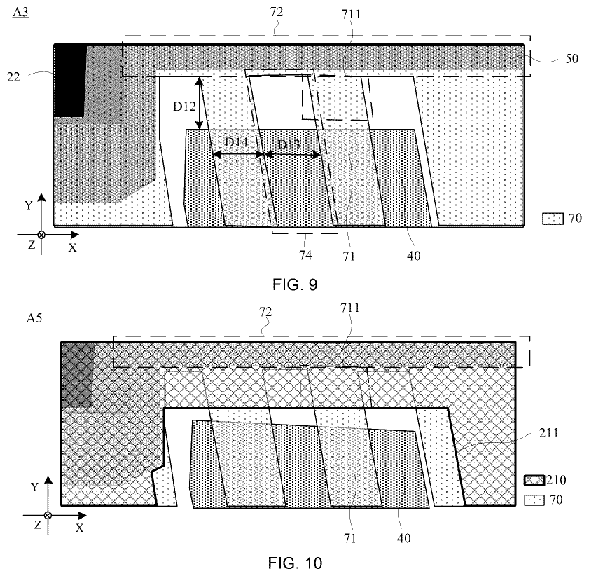

In some embodiments, referring to FIG. 8 and FIG. 9, the common electrode 70 also includes a plurality of slits 74 disposed at intervals along the first direction X. An electrode stripe 71 is included between two adjacent slits 74. Along the first direction X, a size D13 of the slit 74 is larger than a size D14 of the electrode stripe 71, which is conducive to increasing the area of the region of the opening of the common electrode 70 located within the display region AA, and improving the light transmittance of the common electrode 70, thereby improving the light transmittance of the display panel.

In some embodiments, referring to FIG. 7, the size of the slit 74 is D13 along the first direction X, and D13 is 2.7 μm to 2.9 μm. In this way, the strength of the electric field formed between the common electrode 70 and the pixel electrode 40 may be balanced in a case of improving the transmittance of the display panel. Exemplarily, the size of the slit 74 along the first direction X is D13, which may be 2.7 μm, 2.75 μm, 2.8 μm, or 2.9 μm, etc., which will not be enumerated in the embodiments of the present disclosure. It can be understood that if D13 is too small (e.g., less than 2.7 μm), it is not conducive to improving the light transmittance of the display panel, and if D13 is too large (e.g., greater than 2.9 μm), the interval between the electrode stripes 71 is too large, which may affect the strength of the electric field formed between the electrode stripe 71 and the pixel electrode 40. Based on this, in the embodiments of the present disclosure, D13 is 2.7 μm to 2.9 μm.

The size of the electrode stripe 71 is D14 along the first direction X, and D14 is 1.9 μm to 2.1 μm. In this way, it may reduce the difficulty of processing the electrode stripe 71, and reduce the resistance and voltage drop on the electrode stripe 71. Exemplarily, the size of the electrode stripe 71 along the first direction X is D14, which may be 1.9 μm, 2.0 μm, 2.05 μm, or 2.1 μm, etc., which will not be enumerated by the embodiments of the present disclosure. It can be understood that if D14 is too small (e.g., less than 1.9 μm), the process of patterning the common electrode 70 will require high processing precision and the resistance on the electrode stripe 71 will be relatively high, the voltage drop on the electrode stripe 71 is relatively significant, and the uniformity of the electric field formed between the common electrode 70 and the pixel electrode 40 is poor. If D14 is too large (e.g., greater than 2.1 μm), the width of the electrode stripe 71 is large, which is not conducive to improving the light transmittance of the display panel 1100. Based on this, in the embodiments of the present disclosure, D14 is 1.9 μm to 2.1 μm.

Referring to FIG. 8 and FIG. 9, along the second direction Y, an orthographic projection of an end (hereinafter referred to as a fourth end 711) of the electrode stripe 71 away from the drain pattern 24 on the base 10 is located outside of a range of an orthographic projection of the pixel electrode 40 on the base 10. That is, the orthographic projection of the end (the fourth end 711) of the electrode stripe 71 away from the drain pattern 24 on the base 10 covers and extends out of at least a part of a boundary of the orthographic projection of the pixel electrode 40 on the base 10. In this way, it is conducive to reducing the size of the black matrix 210 in the second direction Y, thereby increasing the size of the opening 2101 on the black matrix 210 along the second direction, increasing the area of the light-emitting region AA, and improving the aperture ratio of the display panel.

It can be understood that, referring to FIG. 8, the common electrode 70 also includes a sixth sub-portion 72 connected to the fourth end 711 of the electrode stripe 71. A direction of an electric field formed between the pixel electrode 40, and the fourth end 711 and the sixth sub-portion 72 of the common electrode 70 is not consistent with a direction of an electric field formed between the pixel electrode 40 and other portions (e.g., a middle portion along the second direction Y) of the electrode stripe 71, which may result in the deflected angle of the liquid crystal molecules in the liquid crystal layer 300 in a region near the fourth end 711 of the electrode stripe 71 being different from the deflected angle in other regions (e.g., a region near the middle of the electrode stripe 71 along the second direction Y). Referring to FIG. 10, in order to avoid different light transmittance in different regions of the light-emitting region AA, and improve the uniformity of the light-emitting brightness in different regions of the display region, the black matrix 210 needs to cover the fourth end 711 of the electrode stripe 71, and the sixth sub-portion 72. Based on the above, an orthographic projection of an end (the fourth end 711) of the electrode stripe 71 away from the drain pattern 24 on the base 10 is located outside the range of the orthographic projection of the pixel electrode 40 on the base 10, which is conducive to reducing the size of the black matrix 210 along the second direction Y, improving the size of the opening 2101 in the second direction Y, and then improving the aperture ratio of the display panel.

In some embodiments, referring to FIG. 9, along the second direction Y, an interval D12 between the end (the fourth end 711) of the electrode stripe 71 away from the drain pattern 24 and the pixel electrode 40 is 0.9 μm to 1.1 μm. That is, a length of the electrode stripe 71 extending out of the pixel electrode 40 is 0.9 μm to 1.1 μm. In this way, in a case of improving the aperture ratio of the display panel, it may also minimize a length of the electrode stripe 71, and reduce the voltage drop on the electrode stripe 71. Exemplarily, the interval D12 between the fourth end 711 of the electrode stripe 71 and the pixel electrode 40 may be 0.9 μm, 1 μm, or 1.1 μm, etc., which will not be enumerated in the embodiments of the present disclosure.

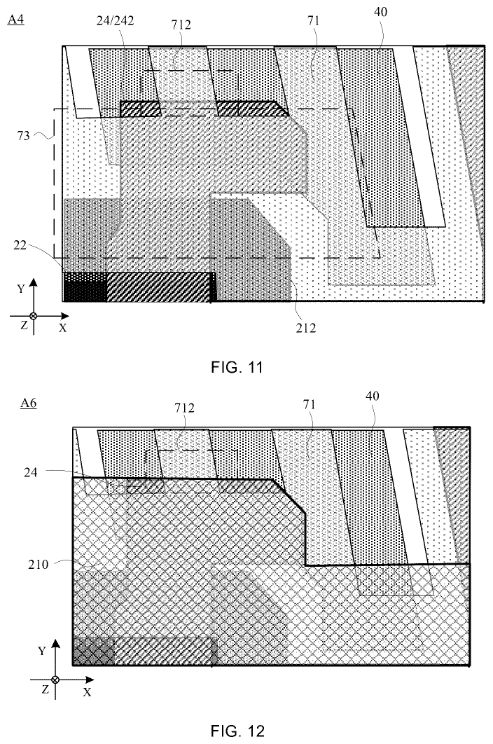

In some embodiments, referring to FIG. 11, along the second direction Y, an orthographic projection of an end (hereinafter referred to as a fifth end 712) of the electrode stripe 71 near the drain pattern 24 on the base 10 is located within the range of the orthographic projection of the pixel electrode 40 on the base 10, and has an interval with a boundary of the orthographic projection of the pixel electrode 40 on the base 10.

Referring to FIG. 12, as described above, the orthographic projection of the black matrix 210 on the array substrate 100 covers the drain pattern 24, and the drain pattern 24 is partially overlapped with the pixel electrode 40, so that the black matrix 210 also covers at least a part of the region of the pixel electrode 40 near the thin film transistor 20, and based on this, the orthographic projection of the fifth end 712 of the electrode stripe 71 on the base 10 is located within the range of the orthographic projection of the pixel electrode 40 on the base 10, which will not increase the width of the black matrix 210 along the second direction Y, and thus, will not reduce the aperture ratio of the display panel 1100, and furthermore, which is conducive to simplifying the manufacturing difficulty of the common electrode 70.

Exemplarily, referring to FIG. 12, the orthographic projection of the end portion (the fifth end 712) of the electrode stripe 71 near the drain pattern 24 on the base 10 partially overlaps with the orthographic projection of the drain pattern 24 on the base 10, that is, the fifth end 712 of the electrode stripe 71 covers a part of the region of the drain pattern 24, which may reduce the size of the black matrix 210 along the second direction Y, and then improve the aperture ratio of the display panel, without increasing the size of the black matrix 210 along the second direction Y. Moreover, the black matrix may be enabled to cover the fifth end 712 of the electrode stripe 71, and the uniformity of the brightness of the display region AA may be improved, without increasing the size of the black matrix 210.

Referring to FIG. 11, the common electrode 70 also includes a first connecting portion 73, and the first connecting portion 73 is connected with the end portion (the fifth end 712) of the electrode stripe 71 near the drain pattern 24. The first connecting portion 73 can connect the two electrode stripes 71 as a whole, which is conducive to reducing the resistance of the electrode stripes 71, reducing the voltage drop of the common electrode 70, and improving the voltage stability of the common electrode 70. An orthographic projection of the first connecting portion 73 on the base 10 partially overlaps with the orthographic projection of the pixel electrode 40 on the base 10, which is, without affecting (without reducing) the aperture ratio of the display panel, conducive to improving the value of the storage capacitor Cst (as shown in FIG. 9) between the common electrode 70 and the pixel electrode 40, improving the voltage holding capability of the pixel electrode 40, and improving the stability of the electric field formed between the pixel electrode 40 and the common electrode 70, within a display period.

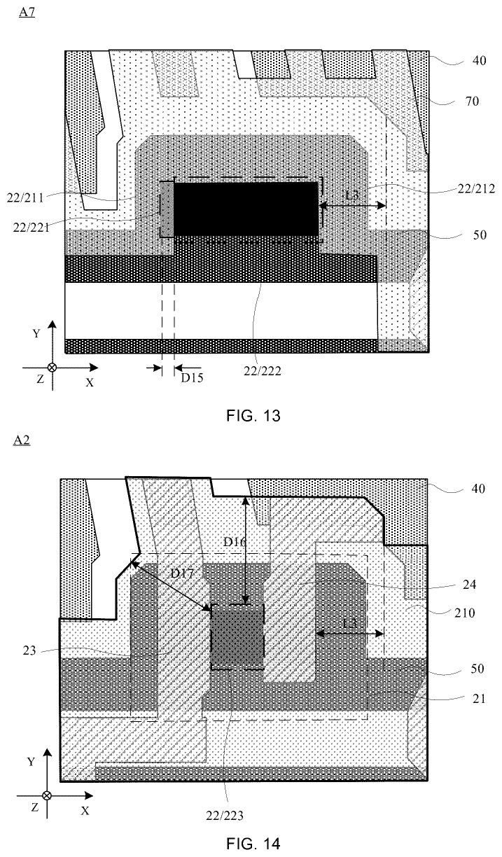

In some embodiments, referring to FIG. 13, the semiconductor pattern 22 includes a third sub-portion 221 and a fourth sub-portion 222 arranged along the first direction X, and the third sub-portion 221 is near the first sidewall 211, compared to the fourth sub-portion 222. An orthographic projection of the common electrode 70 on the base 10 covers an orthographic projection of the third sub-portion 221 on the base 10, and does not overlap with an orthographic projection of the fourth sub-portion 222 on the base 10. That is, the orthographic projection of the common electrode 70 on the base 10 partially overlaps with the orthographic projection of the semiconductor pattern 22 on the base 10, and the mutually overlapped region is located at an end of the semiconductor pattern 22 near the first sidewall 211. In other words, the mutually overlapped part of the orthographic projection of the semiconductor pattern 22 with the orthographic projection of the common electrode 70 on the base 10 is the third sub-portion 221, and the other parts are the fourth sub-portion 222. As described above, due to the small interval D1 between the semiconductor pattern 22 and the first sidewall 211, the orthographic projection of the common electrode 70 on the base 10 covers the third sub-portion 221, which may reduce the risk of light being emitted from a side of the first sidewall 211 obliquely onto the semiconductor pattern 22, and improve the light-emitting efficiency of the light-emitting region. It can be understood that the second conductive layer 102 (the source pattern 23 and the drain pattern 24) is omitted in FIG. 13, in order to facilitate the illustration of the positional relationship between the common electrode 70 and the semiconductor pattern 22 in FIG. 13.

In some embodiments, along the first direction X, the size of the third sub-portion 221 is D15, and D15 is 0.4 μm to 0.6 μm. That is, the width of which the orthographic projection of the common electrode 70 on the base 10 covers the orthographic projection of the semiconductor pattern 22 on the base 10 is 0.4 μm to 0.6 μm. In this way, it may reduce the risk of light being emitted obliquely onto the semiconductor pattern 22, and at the same time, may also reduce the impact of the common electrode 70 on the conductivity of the semiconductor pattern 22, and improve the stability of the thin film transistor 20.

In some embodiments, referring to FIG. 13, a boundary of the orthographic projection of the common electrode 70 on the base 10 roughly overlaps with an orthographic projection of a boundary (right boundary) of the fourth sub-portion 222 away from the third sub-portion 221 on the base 10, and roughly overlaps with an orthographic projection of a boundary of the fourth sub-portion 222 near the pixel electrode 40 on the base 10. In this way, it is conducive to reducing the area facing between the common electrode 70 and the semiconductor pattern 22, and reducing the impact of the voltage of the common electrode 70 on the semiconductor pattern 22. Also, the area of the common electrode 70 is maximized, and the resistance and voltage drop of the common electrode 70 are reduced.

It should be noted that, due to factors such as the measurement errors and process errors, the boundary of the orthographic projection of the common electrode 70 on the base 10 roughly overlaps with the orthographic projection of the right boundary of the fourth sub-portion 222 on the base 10, which may be understood as that the two (the boundary of the orthographic projection of the common electrode 70 on the base 10 and the orthographic projection of the right boundary of the fourth sub-portion 222 on the base 10) completely overlap, or at least partially have an interval which is within an acceptable deviation range, and the acceptable deviation range may be, for example, less than or equal to 0.5 μm, 1 μm, or 2 μm, etc. Also, in other embodiments of the present disclosure, when describing that projections of two components roughly overlap, it may be understood as that the projections of the two components completely overlap, or at least a part of boundaries of the projections of the two components have a certain interval which is within the acceptable deviation range.

Of course, in some other embodiments, the boundary of the orthographic projection of the common electrode 70 on the base 10 may have a certain interval with a boundary (right boundary) of the fourth sub-portion 222 away from the third sub-portion 221; and/or, the boundary of the orthographic projection of the common electrode 70 on the base 10 may have a certain interval with a boundary (upper boundary) of the fourth sub-portion 222 near the pixel electrode 40. That is, as long as the orthographic projection of the common electrode 70 on the base 10 does not overlap with the orthographic projection of the fourth sub-portion 222 on the base 10, in this way, it is conducive to reducing the impact of the voltage of the common electrode 70 on the semiconductor pattern 22.

In some embodiments, referring to FIG. 14, a boundary of the orthographic projection of the black matrix 210 on the base 10 of the array substrate 100 has intervals with boundaries of orthographic projections of the gate pattern 21, the semiconductor pattern 22, and the source pattern 23 of the thin film transistor 20 on the base 10, and in a case where the drain pattern 24 includes the first sub-portion 241 and the second sub-portion 242, the boundary of the black matrix 210 on the base 10 of the array substrate 100 roughly overlaps with a boundary (upper boundary) of the second sub-portion 242 away from the first sub-portion 241. In this way, it may minimize the size of the black matrix 210 along the second direction Y, thereby increasing the area of the opening 2101 on the black matrix 210, increasing the area proportion of the display region AA, and improving the aperture ratio of the display panel 1100. It can be understood that the common electrode 70 is omitted in FIG. 14, in order to more clearly illustrate the positional relationship between the black matrix 210 and the thin film transistor 20.

In some embodiments, continuing to refer to FIG. 14, along the second direction Y, an interval between the boundary of the orthographic projection of the black matrix 210 on the base 10 and the boundary of the orthographic projection of the semiconductor pattern 22 on the base 10 is D16, and D16 is 6.4 μm to 6.7 μm. And/or, the semiconductor pattern 22 includes a fifth sub-portion 223, the fifth sub-portion 223 is located between the source pattern 23 and the drain pattern 24, and a minimum interval between the orthographic projection of the fifth sub-portion 223 on the base 10 and the boundary of the orthographic projection of the black matrix 210 on the base 10 is D17, and D17 is 5.7 μm to 6.0 μm. In this way, it may increase the width of which the black matrix 210 shields the semiconductor pattern 22 in the second direction Y, thereby reducing the risk of light emitted from the front side into the display panel being emitted onto the semiconductor pattern 22, ensuring that the thin film transistor 20 can work stably, and at the same time, enabling the black matrix 210 to cover the gate pattern 21, the source pattern 23, and the drain pattern 24.

Exemplarily, along the second direction Y, the interval D16 between the boundary of the black matrix 210 and the boundary of the semiconductor pattern 22 may be 6.4 μm, 6.55 μm, 6.6 μm, or 6.7 μm, etc., which will not be enumerated in the embodiments of the present disclosure. Exemplarily, a minimum interval D17 between the orthographic projection of the fifth sub-portion 223 and the orthographic projection of the black matrix 210 on the base 10 is 5.7 μm, 5.85 μm, 5.9 μm, or 6.0 μm, etc., which will not be enumerated in the embodiments of the present disclosure.

In some embodiments, referring to FIG. 4, the array substrate 100 includes a plurality of base platforms 80 arranged in an array, and the plurality of base platforms 80 are disposed on a same layer as the source pattern 23 and the drain pattern 24, and all disposed on the second conductive layer 102. Exemplarily, as shown in FIG. 4, the base platform 80 and the common voltage signal line 60 are connected as a whole, and a size of the base platform 80 along the first direction X is larger than a size of the common voltage signal line 60 along the first direction X.

Exemplarily, a shape of an orthographic projection of the base platform 80 on the base 10 may be hexagonal, octagonal, circular, or oval, etc., which is not specifically limited to the embodiments of the present disclosure. For example, as shown in FIG. 4, the shape of the orthographic projection of the base platform 80 on the base 10 is octagonal.

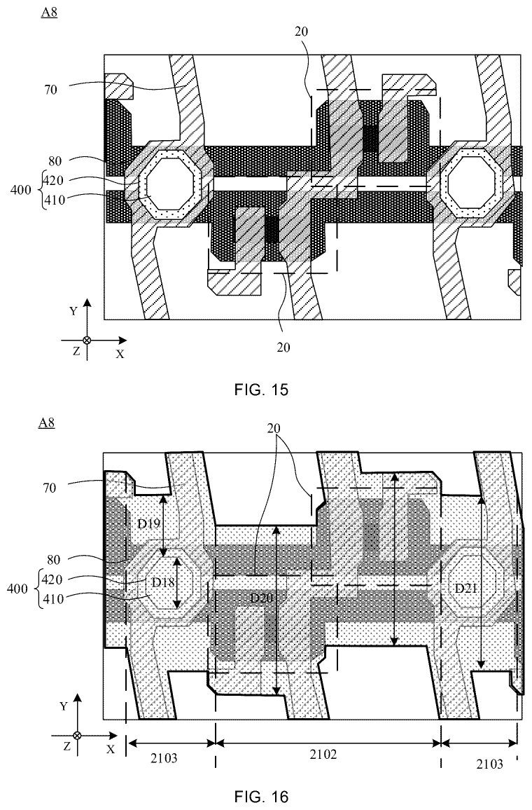

Referring to FIG. 15 and FIG. 16, the display panel 1100 also includes a spacer 400, and the spacer 400 is located between the array substrate 100 and the color film substrate 200, and connected to the array substrate 100 and the color film substrate 200 respectively. The spacer 400 can play a role in supporting the array substrate 100 and the color film substrate 200, so that an interval between the array substrate 100 and the color film substrate 200 is uniformly equal, that is, the thickness of each region of the liquid crystal layer 300 is uniformly equal along the third direction Z, which is conducive to improving the uniformity of the brightness of the display panel. Herein, in order to clearly illustrate the positional relationship between the spacer and the base platform 80, the pixel electrode 40 and the common electrode 70 in the array substrate are omitted and the black matrix 210 is omitted in FIG. 15; and FIG. 16 is a graphic obtained by adding the black matrix 210 on the basis of FIG. 15.

It can be understood that the spacer 400 is a prismatic platform structure, as shown in FIG. 15, and an end surface of the spacer 400 in contact with the color film substrate 200 is a first end surface 410, and a surface in contact with the array substrate 100 is a second end surface 420. An orthographic projection of the first end surface 410 on the base platform 80 is located within a range of an orthographic projection of the second end surface 420 on the base platform 80, and a boundary of the first end surface 410 has an interval with a boundary of the second end surface 420.

An orthographic projection of the spacer 400 on the base 10 is located within a range of an orthographic projection of the base platform 80 on the base 10. For example, an orthographic projection of the second end surface 420 on the base platform 80 is located within a range of the base platform 80. The base platform 80 may play a role in supporting the spacer 400, so that the array substrate 100 is subjected to a uniform force, thereby reducing the risk of the array substrate 100 being squeezed and deformed by the spacer 400.

A shape of the orthographic projection of the spacer 400 on the base 10 may be or may not be the same as a shape of the orthographic projection of the base platform 80 on the base 10. Exemplarily, the shape of the orthographic projection of the spacer 400 on the base 10 may also be hexagonal, octagonal, circular, or oval, etc., which is not specifically limited to the embodiments of the present disclosure. For example, as shown in FIG. 15, the shape of the orthographic projection of the spacer 400 on the base 10 and the shape of the orthographic projection of the base platform 80 on the base 10 are the same, and both are octagonal.

Referring to FIG. 16, the black matrix 210 includes a first extending segment 2102 and a second extending segment 2103. An orthographic projection of the first extending segment 2102 on the base 10 covers the orthographic projection of the thin film transistor 20 on the base 10. An orthographic projection of the second extending segment 2103 on the base 10 covers orthographic projections of the base platform 80 and the spacer 400 on the base 10. Along the second direction Y, a size D20 of the first extending segment 2102 is smaller than a size D21 of the second extending segment 2103. That is, the size of the black matrix 210 along the second direction Y may be flexibly set according to a difference in sizes of the thin film transistor 20 and the base platform 80 along the second direction Y, and in this way, it is conducive to reducing the size of the black matrix 210, improving the area of the opening 2101 on the black matrix 210, and improving the aperture ratio of the display panel 1100.

In some embodiments, a radial size of an end surface (hereinafter referred to as a first end surface 410) at which the spacer 400 is connected to the color film substrate 200 is D18, and D18 is 8.3 μm to 8.7 μm. On the one hand, it may reduce a pressure intensity of a position at which the color film substrate 200 contacts with the spacer 400 and reduce the risk of the color film substrate 200 being destroyed by squeezing, and on the other hand, it is conducive to reducing the size of the spacer 400, thereby reducing the area of the black matrix 210, improving the area of the opening 2101 on the black matrix 210, and improving the aperture ratio of the display panel. Exemplarily, the radial size D18 of the first end surface 410 of the spacer 400 may be 8.3 μm, 8.5 μm, or 8.7 μm, etc., which will not be enumerated in the embodiments of the present disclosure.

It can be understood that the radial size of the first end surface 410 is an interval between two opposite side edges of the first end surface 410. Exemplarily, in a case where a shape of the first end surface 410 is octagonal, as shown in FIG. 16, the radial size of the first end surface 410 may be an interval between two side edges disposed opposite to each other along the second direction Y. Of course, in a case where the shape of the first end surface 410 is circular, the radial size of the first end surface 410 is a diameter of the first end surface 410.

A minimum interval between an orthographic projection of the end surface (the first end surface 410), at which the spacer 400 is connected to the color film substrate 200, on the black matrix 210, and the boundary of the black matrix 210 is D19, and D19 is 6.8 μm to 7.2 μm. That is, the black matrix 210 covers the first end surface 410 of the spacer 400, which may reduce the risk of the light leakage of the liquid crystal layer 300 in the proximity of the spacer 400, and minimize the area on the black matrix 210, increasing the area of the opening 2101, and improving the aperture ratio of the display panel. Exemplarily, the minimum interval between the first end surface 410 of the spacer 400 and the boundary of the black matrix 210 may be 6.8 μm, 7.0 μm, or 7.2 μm, etc., which will not be enumerated in the embodiments of the present disclosure.

In some embodiments, referring to FIG. 2, the orthographic projection of the black matrix on the base 10 also covers orthographic projections of the gate line, the data line, and the common voltage signal line 60 on the base 10, to reduce the reflection of light that is emitted into the display panel from outside, by the gate line, the data line, and the common voltage signal line.

The above description is merely the specific implementation of the present disclosure, but the protection scope of the present disclosure is not limited thereto. All changes or substitutions that any person skilled in this art who is familiar with this technology field may think of within the technical scope disclosed by the present disclosure, should be covered within the protection scope of the present disclosure. Therefore, the protection scope of the present disclosure should be based on the protection scope of the stated claims.

1. An array substrate, comprising a base, and a plurality of thin film transistors disposed on the base and distributed in an array, wherein a thin film transistor of the plurality of this film transistors comprises:
a gate pattern, disposed on the base;
a semiconductor pattern, disposed on a side of the gate pattern away from the base, wherein an orthographic projection of the semiconductor pattern on the base is located within a range of an orthographic projection of the gate pattern on the base, and a boundary of the orthographic projection of the semiconductor pattern on the base has an interval with a boundary of the orthographic projection of the gate pattern on the base;
a source pattern and a drain pattern, wherein the source pattern and the drain pattern are disposed at intervals along a first direction, and electrically connected to two ends of the semiconductor pattern along the first direction, respectively;
wherein the gate pattern comprises a first sidewall and a second sidewall disposed opposite to each other along the first direction, the first sidewall is near the source pattern, and the second sidewall is near the drain pattern; and along the first direction, an interval between an end of the source pattern near the first sidewall and the semiconductor pattern is less than an interval between an end of the drain pattern near the second sidewall and the semiconductor pattern, and an interval between the semiconductor pattern and the first sidewall is less than an interval between the semiconductor pattern and the second sidewall.

2. The array substrate according to claim 1, wherein the gate pattern further comprises a third sidewall and a fourth sidewall disposed opposite to each other along a second direction, the second direction intersects with the first direction; and an interval between the semiconductor pattern and the third sidewall, an interval between the semiconductor pattern and the fourth sidewall, and the interval between the semiconductor pattern and the second sidewall are roughly equal; or
the interval between the semiconductor pattern and the first sidewall is D1, the interval between the semiconductor pattern and the second sidewall is D2, and a ratio of D1 to D2 is 0.5 to 0.6.

3. (canceled)

4. The array substrate according to claim 1, wherein the drain pattern comprises:
a first sub-portion, extending along a second direction and electrically connected to the semiconductor pattern, wherein an orthographic projection of the first sub-portion on the base is located within a range of the orthographic projection of the gate pattern on the base, and the second direction intersects with the first direction; and
a second sub-portion, connected with the first sub-portion, wherein along the first direction, an orthographic projection of an end portion of the second sub-portion away from the first sub-portion on the base is flush with an orthographic projection of the second sidewall on the base, or extends out of the boundary of the orthographic projection of the gate pattern on the base.

5. The array substrate according to claim 1, wherein
along the first direction, a size of an overlapped part of the source pattern with the semiconductor pattern and a size of an overlapped part of the drain pattern with the semiconductor pattern are roughly equal; and a size of the semiconductor pattern along a second direction is greater than an interval between the source pattern and the drain pattern; or
along the first direction, a size of an overlapped part of the source pattern with the semiconductor pattern and a size of an overlapped p io pattern with the semiconductor pattern are roughly equal; and a size of conductor pattern along a second direction is greater than an interval between the source pattern and the drain pattern; and along the first direction, a size of an overlapped part of the source pattern with the semiconductor pattern and a size of an overlapped part of the drain pattern with the semiconductor pattern are D3, and D3 is 3 μm to 3.85 μm; a size of the semiconductor pattern along the second direction is D4, and D4 is 3 μm to 3.7 μm; and the interval between the source pattern and the drain pattern is D5, and D5 is 1.8 μm to 2.4 μm.

6. (canceled)

7. The array substrate according to claim 1, further comprising:
a pixel electrode, located on a same film layer as the semiconductor pattern, wherein an orthographic projection of the pixel electrode on the base has an interval with the orthographic projection of the gate pattern on the base, the pixel electrode comprises a lap joint portion, and the lap joint portion is electrically connected to the drain pattern; and a size of the lap joint portion along the first direction is greater than a size of the lap joint portion along a second direction; or
a pixel electrode, located on a same film layer as the semiconductor pattern, wherein an orthographic projection of pixel electrode on the base has an interval with the orthographic projection of the gate pattern on the base, the pixel electrode comprises a lap joint portion, and the lap joint portion is electrically connected to the drain pattern; and a size of the lap joint portion along the first direction is greater than a size of the lap joint portion along a second direction; and the size of the lap joint portion along the first direction is D6, and D6 is 6.1 μm to 1.8 μm.

8. (canceled)

9. The array substrate according to claim 7, further comprising:
a plurality of data lines and a plurality of common voltage signal lines that are arranged in alternating lines along the first direction, wherein the plurality of data lines and the plurality of common voltage signal lines are disposed on a same layer as the source pattern and the drain pattern;
an interval between orthographic projections of the pixel electrode and a common voltage signal line of the plurality of common voltage signal lines on the base is less than an interval between orthographic projections of the pixel electrode and a data line of the plurality of data lines on the base.

10. The array substrate according to claim 9, further comprising:
a plurality of gate lines, arranged at intervals along the second direction and disposed on a same layer as the gate pattern, wherein each gate line of the plurality of gate lines extends along the first direction, and a gate line of the plurality of gate lines is electrically connected to the gate pattern, wherein along the second direction, an interval between the pixel electrode and the gate pattern. and an interval between the pixel electrode and the gate line are equal; or
a plurality of gate lines, arranged at intervals along the second direction and disposed on a same layer as the gate pattern, wherein each gate line of the plurality of gate lines extends along the first direction, and a gate line of the plurality of gate lines is electrically connected to the gate pattern, wherein along the second direction, an interval between the pixel electrode and the gate pattern, and an interval between the pixel electrode and the gate line are equal, and the interval between the pixel electrode and the gate pattern is less than the interval between the pixel electrode and the common voltage signal line.

11. (canceled)

12. The array substrate according to claim 9, 1, wherein along the first direction, a size of the data line is roughly equal to a size of the common voltage signal line, and the size of the data line along the first direction is smaller than a size of an overlapped part of the source pattern with the semiconductor pattern along the first direction.

13. The array substrate according to claim 12, wherein an interval between the pixel electrode and the common voltage signal line along the first direction is D8, and D8 is 2.4 μm to 2.8 μm;
an interval between the pixel electrode and the data line along the first direction is D9, and D9 is 3.0 μm to 3.4 μm;
an interval between the pixel electrode and a grid line comprised in the array substrate along the second direction is D10, and D10 is 2.0 μm to 2.4 μm; and
sizes of the data line and the common voltage signal line along the first direction are D11, and D11 is 2.4 μm to 2.8 μm.

14. The array substrate according to claim 7, further comprising:
a common electrode, located on a side of the source pattern and the drain pattern away from the base, and comprising at least one electrode stripe extending along the second direction; and
along the second direction, an orthographic projection of an end of an electrode stripe of the at least one electrode stripe away from the drain pattern on the base is located outside a range of the orthographic projection of the pixel electrode on the base.

15. The array substrate according to claim 14, wherein
along the second direction, an orthographic projection of an end of the electrode stripe near the drain pattern on the base is located within the range of the orthographic projection of the pixel electrode on the base, and partially overlaps with an orthographic projection of the drain pattern on the base; and the summon electrode further comprises a first connecting portion, the first connecting portion is connected with an end portion of the electrode stripe near the drain pattern; an orthographic projection of the first connecting portion on the base partially overlaps with the orthographic projection of the pixel electrode on the base; or
the common electrode further comprises a plurality of slits disposed at intervals along the first direction, and an electrode stripe of the at least one electrode stripe is comprised between two adjacent slits of the plurality of slits; and along the first direction, a size of a slit of the plurality of slits is larger than a size of the electrode stripe.

16. (canceled)

17. The array substrate according to claim 15, wherein
along the second direction, an interval between an end of the electrode stripe away from the drain pattern and the pixel electrode is D12, and D12 is 0.9 μm to 1.1 μm;
the size of the slit along the first direction is D13, and D13 is 2.6 μm to 2.9 μm; and
the size of the electrode stripe along the first direction is D14, and D14 is 1.9 μm to 2.1 μm.

18. The array substrate according to claim 14, wherein
the semiconductor pattern comprises a third sub-portion and a fourth sub-portion arranged along the first direction, and the third sub-portion is near the first sidewall, compared to the fourth sub-portion; and an orthographic projection of the common electrode on the base covers an orthographic projection of the third sub-portion on the base, and does not overlap with an orthographic projection of the fourth sub-portion on the base; or
the semiconductor pattern comprises a third sub-portion and a fourth sub-portion arranged along the first direction, and the third sub-portion is near the first sidewall, compared to the fourth sub-portion; and an orthographic projection of the common electrode on the base covers an orthographic projection of the third sub-portion on the base, and does not overlap with an orthographic projection of the fourth sub-portion on the base; and along the first direction, a size of the third sub-portion is D15, and D15 is 0.4 μm to 0.6 μm; or
the semiconductor pattern comprises a third sub-portion and a fourth sub-portion arranged along the first direction, and the third sub-portion is near the first sidewall, compared to the fourth sub-portion; and an orthographic projection of the common electrode on the base covers an orthographic projection of the third sub-portion on the base, and does not overlap with an orthographic projection of the fourth sub-portion on the base; and a boundary of the orthographic projection of the common electrode on the base roughly overlaps with an orthographic projection of a boundary of the fourth sub-portion away from the third sub-portion on the base, and roughly overlaps with an orthographic projection of a boundary of the fourth sub-portion near the pixel electrode on the base.

19. (canceled)

20. (canceled)

21. A display panel, comprising:
the array substrate according to claim 1; and
a color film substrate disposed opposite to the array substrate, wherein the color film substrate comprises a black matrix, and an orthographic projection of the black matrix on the array substrate covers the thin film transistor of the array substrate.

22. The display panel according to claim 21, wherein the drain pattern of the thin film transistor comprises a first sub-portion and a second sub-portion; and
a boundary of an orthographic projection of the black matrix on the base of the array substrate has intervals with a boundary of an orthographic projection of the gate pattern of the thin film transistor on the base, with a boundary of an orthographic projection of the semiconductor pattern of the thin film transistor on the base, and with a boundary of an orthographic projection of the source pattern of the thin film transistor on the base, and roughly overlaps with a boundary of the second sub-portion away from the first sub-portion.

23. The display panel according to claim 22, wherein
along the second direction, an interval between the boundary of the orthographic projection of the black matrix on the base and the boundary of the orthographic projection of the semiconductor pattern on the base is D16, and D16 is 6.4 μm to 6.7 μm; and/or
the semiconductor pattern comprises a fifth sub-portion, the fifth sub-portion is located between the source pattern and the drain pattern, and a minimum interval between the boundary of the orthographic projection of the black matrix on the base and an orthographic projection of the fifth sub-portion on the base is D17, and D17 is 5.7 μm to 6.0 μm.

24. The display panel according to claim 21,
wherein the array substrate comprises a plurality of base platforms arranged in an array, the plurality of base platforms are disposed on a same layer as the source pattern and the drain pattern;
the display panel further comprises:
a spacer, disposed between the array substrate and the color film substrate, and connected to the array substrate and the color film substrate respectively, wherein an orthographic projection of the spacer on the base is located within a range of an orthographic projection of a base platform of the plurality of base platforms on the base;
the black matrix comprises:
a first extending segment, wherein an orthographic projection of the first extending segment on the base covers an orthographic projection of the thin film transistor on the base; and
a second extending segment, wherein an orthographic projection of the second extending segment on the base covers orthographic projections of the base platform and the spacer on the base;
along the second direction, a size of the first extending segment is smaller than a size of the second extending segment.

25. The display panel according to claim 24, wherein
a radial size of an end surface at which the spacer is connected to the color film substrate is D18, and D18 is 8.3 μm to 8.7 μm; and/or
a minimum interval between an orthographic projection of the end surface at which the spacer is connected to the color film substrate, on the black matrix, and a boundary of the black matrix is D19, and D19 is 6.8 μm to 7.2 μm.

26. The display panel according to claim 21, wherein the array substrate comprises a common electrode, the common electrode comprises at least one electrode stripe extending along a second direction;
an orthographic projection of the black matrix on the array substrate overlaps at least partially with an end portion of electrode stripe of the at least one electrode stripe along the second direction.

27. A display apparatus, comprising:
the display panel according to claim 21; and
a driving circuit board, configured to transmit a control signal to the display panel.
